(19) United States
(12) Patent Application Publication
(10) Pub. No.: US 2026/0262491 A1
(43) Pub. Date: Sep. 3, 2026

(54) SEMICONDUCTOR DEVICE

(71) Applicant: ROHM CO., LTD., Kyoto-shi (JP)

(72) Inventor: Ryohei HASEGAWA, Kyoto-shi, Kyoto (JP)

(21) Appl. No.: 19/656,452

(22) Filed: Apr. 23, 2026

Related U.S. Application Data
(63) Continuation of application No. PCT/JP2024/038455, filed on Oct. 29, 2024.

(30) Foreign Application Priority Data
Nov. 2, 2023 (JP) 2023-188654

(51) Int. Cl. H10W 40/20; H10W 40/25; H10W 74/10; H10W 90/00; H10W 74/15

(52) U.S. Cl. CPC H10W 40/233; H10W 40/257; H10W 74/121; H10W 90/726; H10W 74/15

(57) ABSTRACT

A semiconductor device includes a substrate, substrate terminals extending through the substrate in a thickness-wise direction of the substrate, a semiconductor chip including chip terminals, and a first encapsulation resin. The chip terminals are electrically connected to the substrate terminals. The first encapsulation resin covers a chip head surface and a chip side surface of the semiconductor chip. The substrate terminals include a heat dissipation terminal having a portion located outward from the semiconductor chip as viewed in the thickness-wise direction of the semiconductor chip. The semiconductor device further includes a heat dissipation member being in contact with each of a chip back surface of the semiconductor chip, an encapsulation head surface of the first encapsulation resin, and a terminal head surface of the heat dissipation terminal.

### CROSS-REFERENCE TO RELATED APPLICATIONS

This application is a continuation of, and claims the benefit of priority from International Application No. PCT/JP2024/038455, filed on October 29, 2024, which claims the benefit of priority from Japanese Patent Application No. 2023-188654, filed on November 2, 2023, the entire contents of each are incorporated herein by reference.

### BACKGROUND

### 1. Field

The following description relates to a semiconductor device.

### 2. Description of Related Art

JP2021-5687A discloses a semiconductor device including a substrate, a semiconductor element, and an encapsulation resin. The substrate includes a wiring portion. The encapsulation resin is disposed on the substrate and encapsulates the semiconductor element. The wiring portion includes a main surface wiring part and a through-wiring part. The main surface wiring part is disposed on the substrate. The through-wiring part extends through the substrate. The semiconductor element is mounted on the main surface wiring part.

### BRIEF DESCRIPTION OF THE DRAWINGS

FIG. 1 is a schematic perspective view of a semiconductor device in accordance with an embodiment.

FIG. 2 is a schematic plan view showing the internal structure of the semiconductor device shown in FIG. 1.

FIG. 3 is a schematic back view of the semiconductor device shown in FIG. 1.

FIG. 4 is a schematic cross-sectional view of the semiconductor device taken along line F4-F4 shown in FIG. 2.

FIG. 5 is an enlarged schematic plan view of part of the semiconductor device shown in FIG. 2.

FIG. 6 is an enlarged schematic cross-sectional view of part of the semiconductor device shown in FIG. 4.

FIG. 7 is a schematic plan view illustrating an exemplary manufacturing step of the semiconductor device in accordance with the embodiment.

FIG. 8 is a schematic plan view illustrating a manufacturing step following the step of FIG. 7.

FIG. 9 is a schematic plan view illustrating a manufacturing step following the step of FIG. 8.

FIG. 10 is a schematic plan view illustrating a manufacturing step following the step of FIG. 9.

FIG. 11 is a schematic cross-sectional view of the semiconductor device taken along line F11-F11 shown in FIG. 10, illustrating a manufacturing step following the step of FIG. 10.

FIG. 12 is a schematic cross-sectional view of a semiconductor device of a modified example.

FIG. 13 is a schematic plan view showing the internal structure of a semiconductor device of another modified example.

FIG. 14 is a schematic cross-sectional view of the semiconductor device taken along line F14-F14 shown in FIG. 13.

FIG. 15 is a schematic cross-sectional view of part of a semiconductor device of another modified example.

FIG. 16 is a schematic cross-sectional view of a semiconductor device of another modified example.

FIG. 17 is a schematic cross-sectional view of a semiconductor device of another modified example.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

This description provides a comprehensive understanding of the methods, apparatuses, and/or systems described. Modifications and equivalents of the methods, apparatuses, and/or systems described are apparent to one of ordinary skill in the art. Sequences of operations are exemplary, and may be changed as apparent to one of ordinary skill in the art, with the exception of operations necessarily occurring in a certain order. Descriptions of functions and constructions that are well known to one of ordinary skill in the art may be omitted.

Exemplary embodiments may have different forms, and are not limited to the examples described. However, the examples described are thorough and complete, and convey the full scope of the disclosure to one of ordinary skill in the art.

In this specification, “at least one of A and B” should be understood to mean “only A, only B, or both A and B.”

Several embodiments of a semiconductor device according to the present disclosure will now be described with reference to the accompanying drawings. Elements in the drawings may not be drawn to scale for simplicity and clarity of illustration. In the cross-sectional drawings, hatching lines may not be shown in order to facilitate understanding. The accompanying drawings merely illustrate exemplary embodiments of the present disclosure and are not intended to limit the present disclosure.

This detailed description includes exemplary embodiments of devices, systems, and methods in accordance with the present disclosure. The present description is illustrative and is not intended to limit the embodiments of the present disclosure or application and use of the embodiments.

In this specification, the phrase “at least one of” as used in this disclosure means “one or more” of desired options. In an example, the phrase “at least one of” means “only one of two options” or “both of two options” if the number of options is two. In another example, the phrase “at least one of” means “only one of the options” or “any combination of two or more of the options” if the number of options is three or more.

In this specification, phrases such as “the length (dimension) of A is equal to the length (dimension) of B” and “A and B have the same length (dimension)” includes a relationship in which the difference between the length (dimension) of A and the length (dimension) of B is, for example, within 10% of the length (dimension) of A.

### Embodiment

### Structure of Semiconductor Device

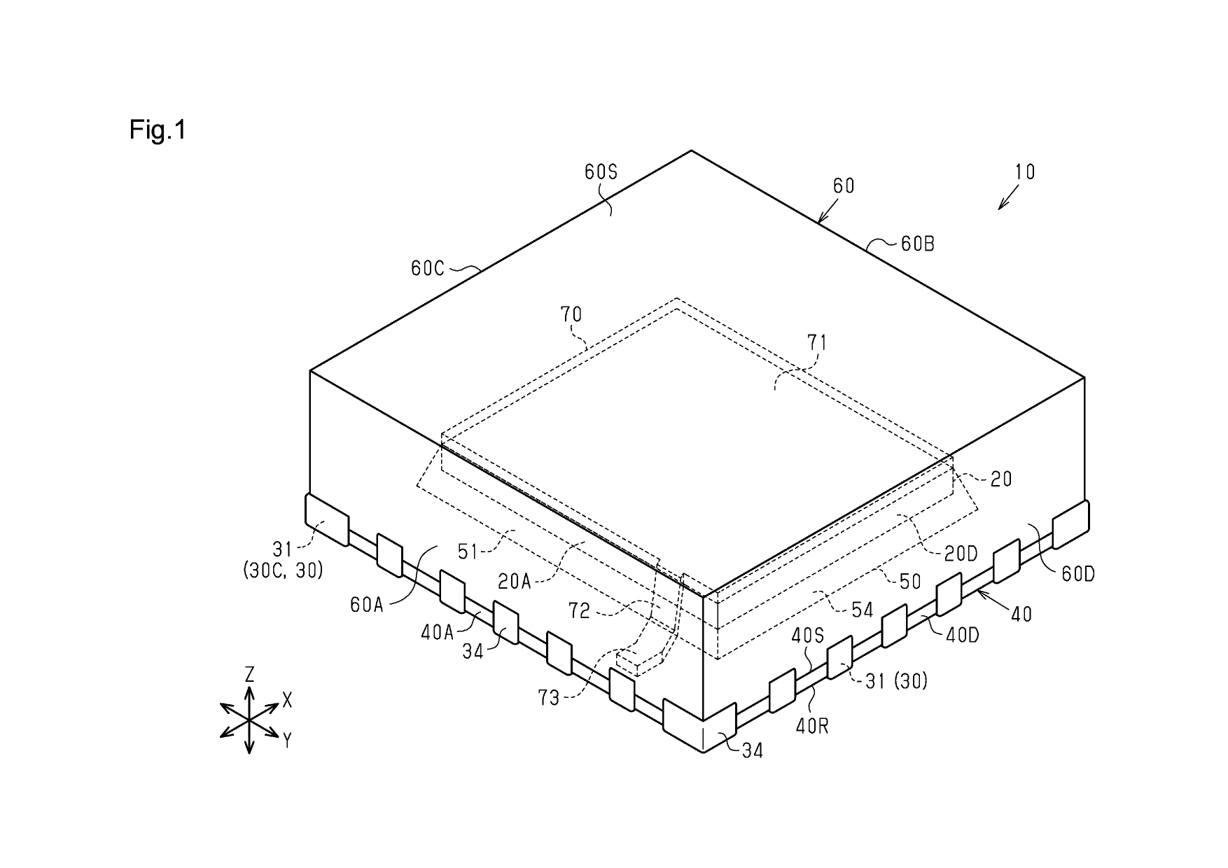

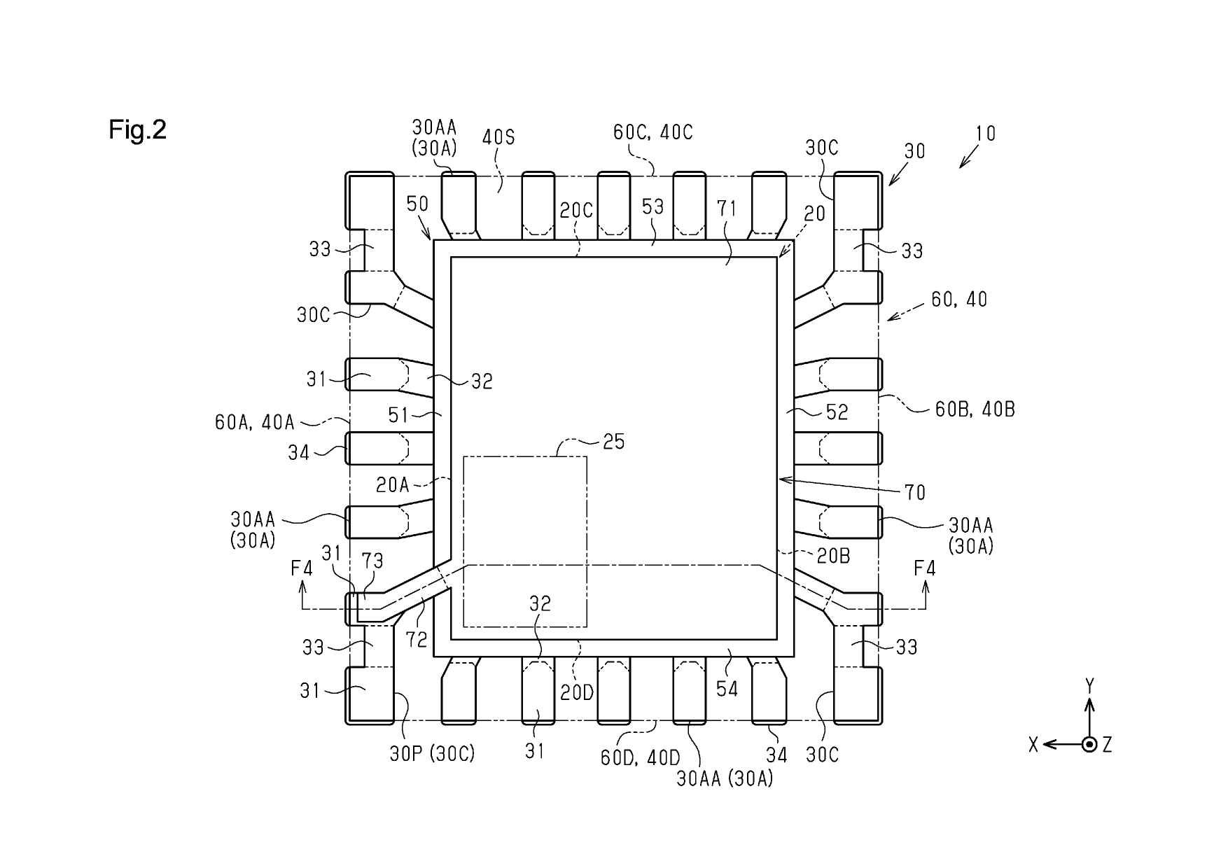

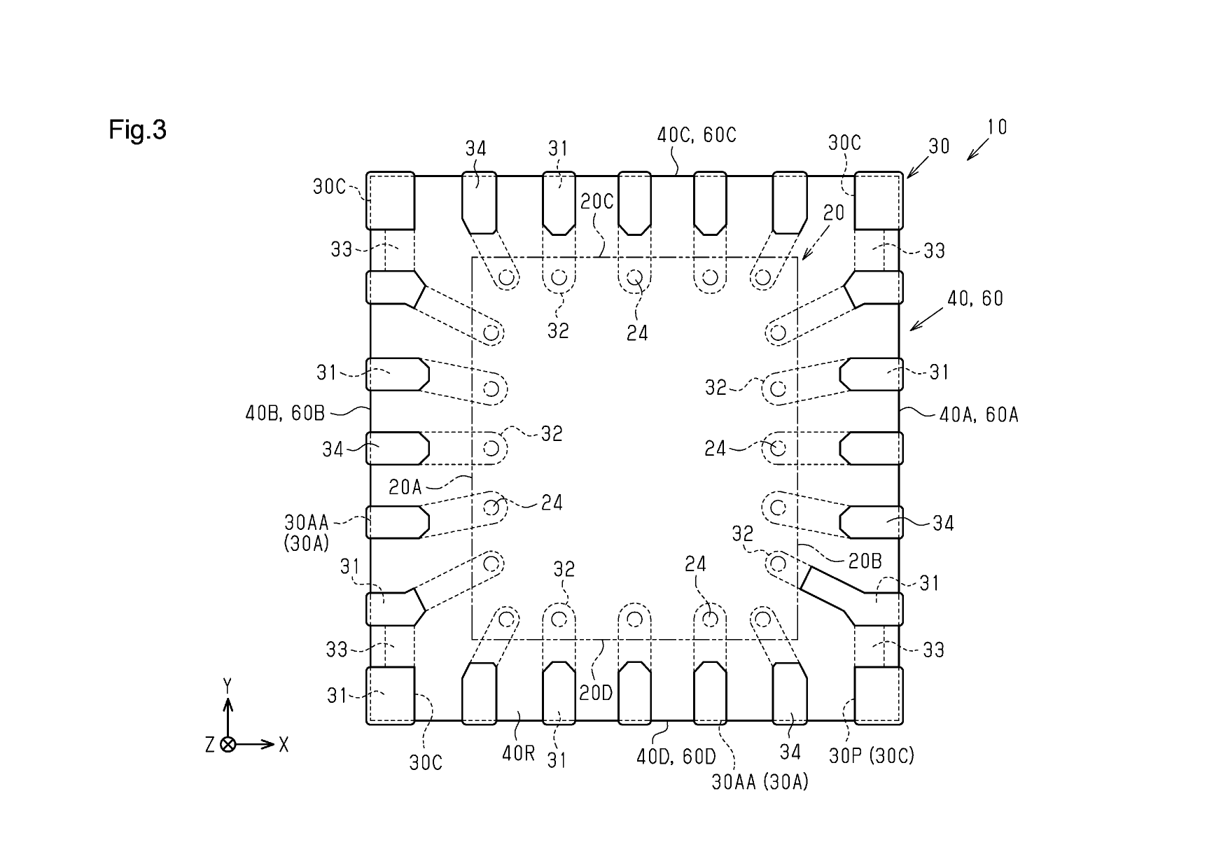

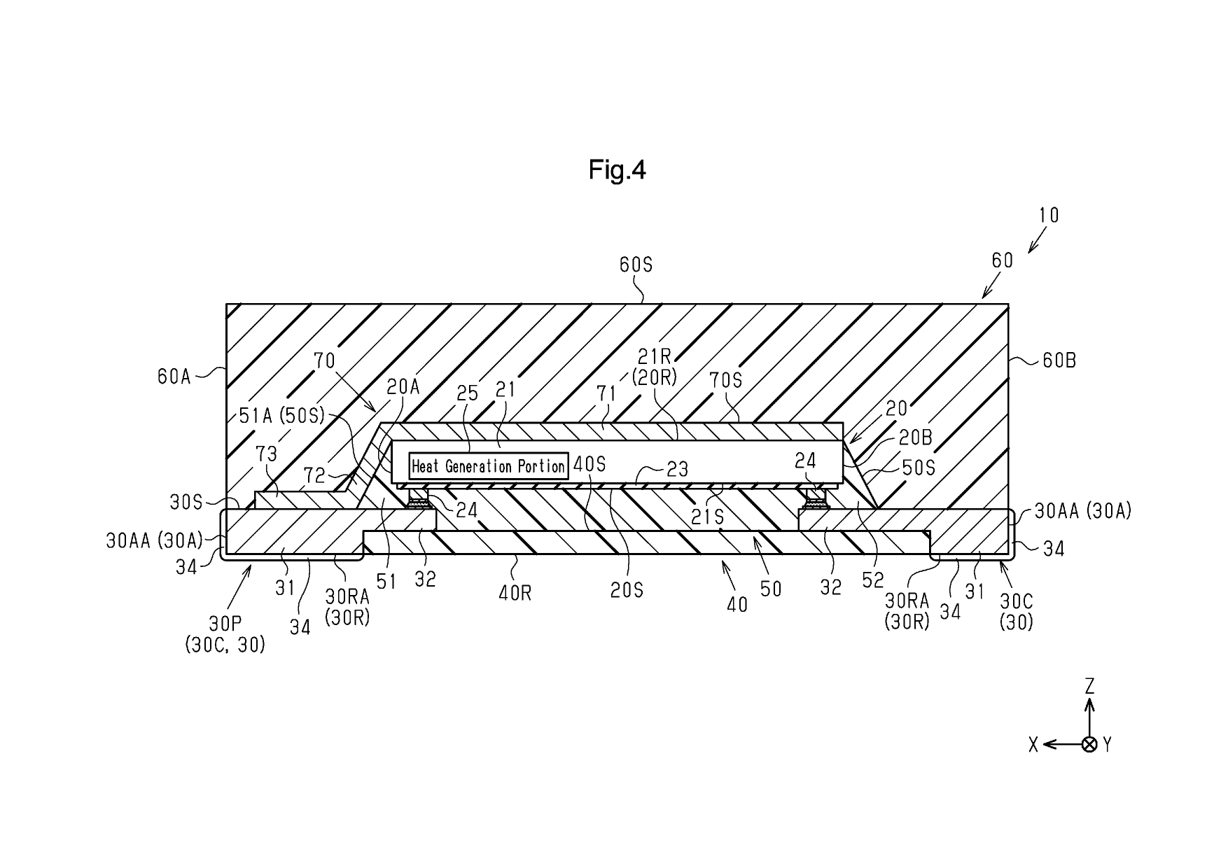

The overall structure of a semiconductor device 10 in accordance with an embodiment will now be described with reference to FIGS. 1 to 4. FIG. 1 is a schematic perspective view showing the structure of the semiconductor device 10. FIG. 2 is a schematic plan view showing the internal structure of the semiconductor device 10. FIG. 3 is schematic back view showing the structure of the semiconductor device 10. FIG. 4 is a schematic cross-sectional view taken along line F4-F4 shown in FIG. 2, showing the structure of the semiconductor device 10. In FIG. 1, broken lines indicate a semiconductor chip 20, a first encapsulation resin 50, and a heat dissipation member 70, which will be described later. In FIG. 2, double-dashed lines indicate a substrate 40 and a second encapsulation resin 60, which will be described later. In FIG. 3, double-dashed lines indicate the semiconductor chip 20. In this specification, X-axis, Y-axis, and Z-axis are orthogonal to one another as shown in FIG. 1. The term “plan view” as used in this disclosure refers to a view of the semiconductor device 10 or elements in the semiconductor device 10 taken in the Z-direction.

As shown in FIGS. 1 and 4, the semiconductor device 10 includes the semiconductor chip 20, substrate terminals 30, the substrate 40, the first encapsulation resin 50, the second encapsulation resin 60, and the heat dissipation member 70. The substrate 40 supports the substrate terminals 30. The semiconductor chip 20 is mounted on the substrate terminals 30. The first encapsulation resin 50 is disposed on the substrate 40 to cover the semiconductor chip 20 and its periphery. The second encapsulation resin 60 is disposed on the substrate 40 and encapsulates the semiconductor chip 20, the first encapsulation resin 50, and the heat dissipation member 70. These components of the semiconductor device 10 will now be described.

### Substrate and Second Encapsulation Resin

As shown in FIG. 1, the substrate 40 and the second encapsulation resin 60 define a device head surface, a device back surface, and device side surfaces of the semiconductor device 10. In the example shown in FIG. 1, the semiconductor device 10 has a rectangular plate shape and has a thickness in the Z-direction.

The substrate 40 has a rectangular plate shape and has a thickness in the Z-direction. That is, the Z-direction is the thickness-wise direction of the substrate 40. The substrate 40 includes a substrate head surface 40S, a substrate back surface 40R, and first to fourth substrate side surfaces 40A to 40D (refer to FIG. 2). The substrate head surface 40S and the substrate back surface 40R face away from each other in the Z-direction. The first to fourth substrate side surfaces 40A to 40D connect the substrate head surface 40S and the substrate back surface 40R. The substrate back surface 40R defines the device back surface of the semiconductor device 10. The first substrate side surface 40A and the second substrate side surface 40B define two end surfaces of the substrate 40 in the X-direction. The third substrate side surface 40C and the fourth substrate side surface 40D define two end surfaces of the substrate 40 in the Y-direction.

The second encapsulation resin 60 includes an encapsulation head surface 60S and first to fourth encapsulation side surfaces 60A to 60D (refer to FIG. 2). The encapsulation head surface 60S faces the same direction as the substrate head surface 40S. The first to fourth encapsulation side surfaces 60A to 60D (refer to FIG. 2) intersect the encapsulation head surface 60S. The encapsulation head surface 60S defines the device head surface of the semiconductor device 10. The first encapsulation side surface 60A and the second encapsulation side surface 60B define two end surfaces of the second encapsulation resin 60 in the X-direction. The third encapsulation side surface 60C and the fourth encapsulation side surface 60D define two end surfaces of the second encapsulation resin 60 in the Y-direction.

The first encapsulation side surface 60A faces the same direction as the first substrate side surface 40A. The second encapsulation side surface 60B faces the same direction as the second substrate side surface 40B. The third encapsulation side surface 60C faces the same direction as the third substrate side surface 40C. The fourth encapsulation side surface 60D faces the same direction as the fourth substrate side surface 40D. In the example shown in FIGS. 1 and 2, the first encapsulation side surface 60A is flush with the first substrate side surface 40A, the second encapsulation side surface 60B is flush with the second substrate side surface 40B, the third encapsulation side surface 60C is flush with the third substrate side surface 40C, and the fourth encapsulation side surface 60D is flush with the fourth substrate side surface 40D. The first encapsulation side surface 60A, the first substrate side surface 40A, the second encapsulation side surface 60B, and the second substrate side surface 40B define two device side surfaces of the semiconductor device 10 located at opposite sides in the X-direction. The third encapsulation side surface 60C, the third substrate side surface 40C, the fourth encapsulation side surface 60D, and the fourth substrate side surface 40D define two device side surfaces of the semiconductor device 10 located at opposite sides in the Y-direction.

### Substrate Terminal

As shown in FIG. 4, the substrate terminals 30 extend through the substrate 40 in the Z-direction. As shown in FIGS. 2 and 3, in plan view, the substrate terminals 30 are arranged along the first to fourth substrate side surfaces 40A to 40D. As shown in FIG. 4, the substrate terminals 30 each include a terminal head surface 30S, a terminal back surface 30R, and terminal side surfaces 30A. The terminal head surface 30S is exposed from the substrate head surface 40S of the substrate 40. The terminal back surface 30R includes a portion exposed from the substrate back surface 40R. The terminal side surfaces 30A connect the terminal head surface 30S and the terminal back surface 30R. As shown in FIGS. 2 and 3, one of the terminal side surfaces 30A of each substrate terminal 30 is exposed from a corresponding one of the first to fourth substrate side surfaces 40A to 40D. The substrate terminals 30 are formed from, for example, a material including copper (Cu), aluminum (Al), or the like. In the present embodiment, the substrate terminals 30 are formed from a material including Cu.

As shown in FIG. 4, each substrate terminal 30 includes a through-wiring portion 31 and a head surface wiring portion 32. The through-wiring portion 31 extends through the substrate 40 in the Z-direction. The head surface wiring portion 32 extends from the through-wiring portion 31 along the substrate head surface 40S. In an example, the through-wiring portion 31 and the head surface wiring portion 32 are integrated to each other. That is, the through-wiring portion 31 and the head surface wiring portion 32 are integrally formed from the same metal material. The substrate terminals 30 are formed by, for example, plating.

The through-wiring portion 31 and the head surface wiring portion 32 may be formed separately. In this case, the through-wiring portion 31 and the head surface wiring portion 32 may be formed from different metal materials.

As shown in FIGS. 2 to 4, in plan view, the through-wiring portions 31 of the substrate terminals 30 are located closer to the first to fourth substrate side surfaces 40A to 40D than the semiconductor chip 20 is. In other words, the through-wiring portions 31 of the substrate terminals 30 are located outward from the semiconductor chip 20 in plan view. Accordingly, the semiconductor device 10 has a fan-out package structure.

The through-wiring portions 31 of the substrate terminals 30 are arranged along the first to fourth substrate side surfaces 40A to 40D in plan view. Each through-wiring portion 31 includes the terminal side surfaces 30A. One of the terminal side surfaces 30A of the through-wiring portion 31 is flush with a corresponding one of the first to fourth substrate side surfaces 40A to 40D. This flush side surface defines an exposed side surface 30AA that is exposed from the corresponding one of the first to fourth substrate side surfaces 40A to 40D. The terminal back surface 30R includes an exposed surface 30RA that is exposed from the substrate 40. The exposed surface 30RA is included in a portion of the terminal back surface 30R that corresponds to the through-wiring portion 31.

A plating layer 34 is formed on both the exposed surface 30RA and the exposed side surface 30AA. The plating layer 34 formed on the exposed surface 30RA projects from the substrate back surface 40R. The plating layer 34 formed on the exposed side surface 30AA projects from a corresponding one of the first to fourth substrate side surfaces 40A to 40D. In the present embodiment, the plating layer 34 formed on the exposed surface 30RA of the terminal back surface 30R is integrated with the plating layer 34 formed on the exposed side surface 30AA. The plating layer 34 includes, for example, at least one of gold (Au), nickel (Ni), tin (Sn), and palladium (Pd).

The head surface wiring portion 32 of the substrate terminal 30 includes a part that extends from the through-wiring portion 31 toward the semiconductor chip 20 in plan view. The head surface wiring portion 32 of the substrate terminal 30 is located at a position that overlaps the semiconductor chip 20 in plan view.

As shown in FIGS. 2 and 3, the substrate terminals 30 disposed at four corners of the substrate 40 in plan view (hereafter, “corner terminals 30C”) each include two through-wiring portions 31. The two through-wiring portions 31 of the corner terminal 30C are located at the same position in the X-direction, and are separated from each other in the Y-direction. The two through-wiring portions 31 are joined by a head surface joining portion 33. The head surface joining portion 33 is disposed on, for example, the substrate head surface 40S of the substrate 40.

In the following description, one of the substrate terminals 30 will be referred to as “heat dissipation terminal 30P”. In an example, the heat dissipation terminal 30P is one of the four corner terminals 30C that is located relatively close to the first substrate side surface 40A and the fourth substrate side surface 40D. Accordingly, the substrate terminals 30 include the heat dissipation terminal 30P that has a portion located outward from the semiconductor chip 20 in plan view. In the same manner as the other substrate terminals 30, the heat dissipation terminal 30P includes the terminal head surface 30S, the terminal back surface 30R facing away from the terminal head surface 30S, and terminal side surfaces 30A connecting the terminal head surface 30S and the terminal back surface 30R. At least part of the terminal side surfaces 30A of the heat dissipation terminal 30P is exposed from the substrate 40. More specifically, the terminal side surface 30A of each of the two through-wiring portions 31 of the heat dissipation terminal 30P faces the same direction as the first substrate side surface 40A, and is exposed from the substrate 40 (first substrate side surface 40A). The terminal side surface 30A is, for example, flush with the first substrate side surface 40A. One of the two through-wiring portions 31 of the heat dissipation terminal 30P that is located relatively close to the corner formed by the first substrate side surface 40A and the fourth substrate side surface 40D has the terminal side surface 30A exposed from the fourth substrate side surface 40D.

As shown in FIGS. 3 and 4, the through-wiring portion 31 of the heat dissipation terminal 30P of the present embodiment extends toward the semiconductor chip 20 further than the through-wiring portion 31 of the other substrate terminal 30 that is not the heat dissipation terminal 30P. Accordingly, the through-wiring portion 31 of the heat dissipation terminal 30P has a greater volume than the through-wiring portion 31 of the other substrate terminal 30 that is not the heat dissipation terminal 30P. In an example, in plan view, the shortest distance from the through-wiring portion 31 of the heat dissipation terminal 30P to the semiconductor chip 20 is less than the shortest distance from the through-wiring portion 31 of the other substrate terminal 30, which is not the heat dissipation terminal 30P, to the semiconductor chip 20.

### Semiconductor Chip

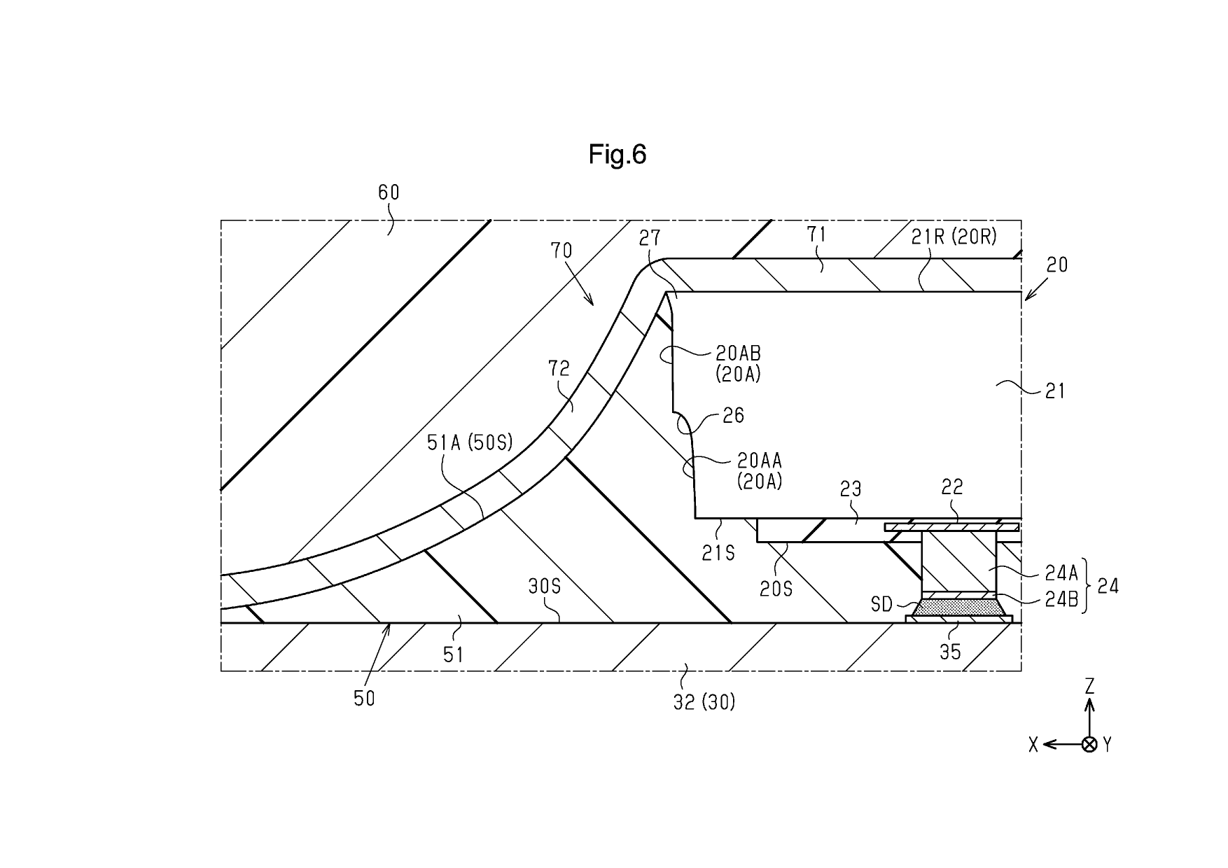

The detailed structure of the semiconductor chip 20, and the mounting structure of the semiconductor chip 20 and the substrate terminals 30 will now be described with reference to FIGS. 3, 4, and 6. FIG. 6 is an enlarged schematic cross-sectional view of part of the semiconductor chip 20 and its surroundings.

As shown in FIG. 4, the semiconductor chip 20 is mounted on the head surface wiring portion 32 of the substrate terminals 30. The semiconductor chip 20 has a rectangular plate shape and has a thickness in the Z-direction. The semiconductor chip 20 includes a semiconductor substrate 21 that defines a chip main body. The semiconductor substrate 21 is formed from, for example, a material including silicon (Si). The semiconductor chip 20 is, for example, a large scale integration (LSI) chip.

The semiconductor substrate 21 includes a main body head surface 21S and a main body back surface 21R that face away from each other in the Z-direction. The main body head surface 21S faces the same direction as the chip head surface 20S of the semiconductor chip 20. The main body back surface 21R faces the same direction as the chip back surface 20R. In the example shown in FIG. 4, the main body back surface 21R defines the chip back surface 20R.

As shown in FIG. 6, the semiconductor chip 20 includes an interconnect 22 that is disposed on the main body head surface 21S of the semiconductor substrate 21, and an insulating layer 23 that covers the main body head surface 21S. Although not shown in the drawings, multiple interconnects 22 are arranged in the insulating layer 23. Each interconnect 22 includes a portion of the semiconductor substrate 21 that faces the head surface wiring portion 32 of the substrate terminal 30 in the Z-direction. The insulating layer 23 includes openings that separately expose the interconnects 22 in the Z-direction. The interconnects 22 are formed from, for example, a material including at least one of Al, Cu, Au, and titanium (Ti).

As shown in FIG. 4, the semiconductor chip 20 includes a heat generation portion 25. The heat generation portion 25 is disposed in the semiconductor substrate 21. The heat generation portion 25 refers to a region of the semiconductor substrate 21 that generates a greater amount of heat than other regions. That is, the heat generation portion 25 is a region of the semiconductor substrate 21 where the temperature is likely to be relatively high. The heat generation portion 25 includes, for example, a transistor.

As shown in FIG. 2, the heat generation portion 25 is located closer to the first chip side surface 20A than the center of the semiconductor substrate 21 (refer to FIG. 4) is in the X-direction. In other words, the center of the heat generation portion 25 in the X-direction is located closer to the first chip side surface 20A than the center of the semiconductor substrate 21 in the X-direction is. In the present embodiment, the X-direction is an example of “first direction”.

In the present embodiment, the heat generation portion 25 is located closer to the fourth chip side surface 20D than the center of the semiconductor substrate 21 is in the Y-direction. In other words, the center of the heat generation portion 25 in the Y-direction is located closer to the fourth chip side surface 20D than the center of the semiconductor substrate 21 in the Y-direction is.

The heat generation portion 25 is electrically connected to, for example, the substrate terminals 30 that are arranged near the heat generation portion 25 and located relatively close to the first chip side surface 20A and the fourth chip side surface 20D in plan view. Accordingly, the heat dissipation terminal 30P is a substrate terminal, which is electrically connected to the heat generation portion 25. The heat dissipation terminal 30P may be insulated from the heat generation portion 25 and electrically connected to a component of the semiconductor chip 20 that is not the heat generation portion 25.

As shown in FIGS. 3 and 4, the semiconductor chip 20 includes chip terminals 24 formed on the chip head surface 20S. The chip terminals 24 are separately bonded to the interconnects 22 (refer to FIG. 6). Each chip terminal 24 is cylindrical and extends from the interconnect 22 in the Z-direction.

As shown in FIG. 6, the chip terminal 24 includes a cylindrical terminal body 24A, and a barrier layer 24B formed on a distal end surface of the terminal body 24A. The chip terminal 24 includes, for example, at least one of Cu, Al, and Ti. The barrier layer 24B is, for example, a plating layer. The barrier layer 24B includes at least one of Au, Ni, and Pd. In an example, the barrier layer 24B is formed from a material including Ni.

A barrier layer 35 is disposed in a region of the head surface wiring portion 32 of each substrate terminal 30 that faces the chip terminal 24 in the Z-direction. In other words, the barrier layer 35 defines part of the terminal head surface 30S. In an example, the barrier layer 35 has a circular shape in plan view. The planar shape of the barrier layer 35 may be changed. The barrier layer 35 includes, for example, at least one of Ni and Ti.

The barrier layer 24B of each chip terminal 24 is bonded to the barrier layer 35 of a corresponding head surface wiring portion 32 by a conductive bonding material SD. As a result, the semiconductor chip 20 is mounted on the head surface wiring portions 32. The barrier layer 35 is a layer that maintains the wettability of the conductive bonding material SD. In this manner, the chip terminals 24 are electrically connected to the head surface wiring portions 32 of the substrate terminals 30. The conductive bonding material SD may be, for example, Ag paste or solder paste.

In the present embodiment, the semiconductor substrate 21 includes a stepped portion 26. The stepped portion 26 is formed in the first chip side surface 20A. The first chip side surface 20A is divided into a head surface-side chip side surface 20AA and a back surface-side chip side surface 20AB. The head surface-side chip side surface 20AA is a portion of the first chip side surface 20A that is located closer to the chip head surface 20S than the stepped portion 26 is. The back surface-side chip side surface 20AB is a portion of the first chip side surface 20A that is located closer to the chip back surface 20R than the stepped portion 26 is. The head surface-side chip side surface 20AA is connected to the chip head surface 20S. The back surface-side chip side surface 20AB is connected to the chip back surface 20R. The back surface-side chip side surface 20AB is curved outward at an end where the back surface-side chip side surface 20AB is connected to the chip back surface 20R. Accordingly, the chip back surface 20R and the back surface-side chip side surface 20AB of the semiconductor chip 20 form a corner 27 that projects outward. Although not shown in the drawings, the stepped portion 26 is also formed in the second to fourth chip side surfaces 20B to 20D (refer to FIG. 2). In other words, the stepped portion 26 extends along the entire periphery of the semiconductor substrate 21.

### First Encapsulation Resin

As shown in FIG. 4, the first encapsulation resin 50 fills the gap between the chip head surface 20S of the semiconductor chip 20 and the substrate head surface 40S of the substrate 40. In other words, the first encapsulation resin 50 covers the chip head surface 20S of the semiconductor chip 20. The first encapsulation resin 50 may also be referred to as an underfill. In the present embodiment, the first encapsulation resin 50 and the second encapsulation resin 60 are formed from different materials. In an example, the first encapsulation resin 50 has a higher thermal conductivity than the second encapsulation resin 60. In an example, the first encapsulation resin 50 has a higher thermal conductivity than air.

As shown in FIGS. 2 and 4, the first encapsulation resin 50 covers the first to fourth chip side surfaces 20A to 20D of the semiconductor chip 20. Accordingly, the first encapsulation resin 50 includes a first cover portion 51 that covers the first chip side surface 20A, a second cover portion 52 that covers the second chip side surface 20B, a third cover portion 53 that covers the third chip side surface 20C, and a fourth cover portion 54 that covers the fourth chip side surface 20D.

In an example, the first cover portion 51 covers the entirety of the first chip side surface 20A in the Z-direction. In an example, the first cover portion 51 covers the entirety of the first chip side surface 20A in the Y-direction. In an example, the second cover portion 52 covers the entirety of the second chip side surface 20B in the Z-direction. In an example, the second cover portion 52 covers the entirety of the second chip side surface 20B in the Y-direction.

In an example, the third cover portion 53 covers the entirety of the third chip side surface 20C in the Z-direction. In an example, the third cover portion 53 covers the entirety of the third chip side surface 20C in the X-direction. In an example, the fourth cover portion 54 covers the entirety of the fourth chip side surface 20D in the Z-direction. In an example, the fourth cover portion 54 covers the entirety of the fourth chip side surface 20D in the X-direction.

In the present embodiment, the first to fourth cover portions 51 to 54 have the same cross-sectional shape. Accordingly, the cross-sectional shape of the first cover portion 51 will be described in detail below with reference to FIG. 6, and the cross-sectional shapes of the second to fourth cover portions 52 to 54 will not be described in detail.

As shown in FIG. 6, the first cover portion 51 includes a sloped surface 51A that is sloped toward the terminal head surface 30S of the heat dissipation terminal 30P as the sloped surface 51A extends away from the first chip side surface 20A. The sloped surface 51A serves as an encapsulation head surface 50S of the first encapsulation resin 50. The sloped surface 51A is connected to the corner 27, which is formed by the chip back surface 20R and the first chip side surface 20A of the semiconductor chip 20. That is, as shown in FIG. 6, the sloped surface 51A is sloped toward the terminal head surface 30S of the heat dissipation terminal 30P from one of two edges of the chip back surface 20R in the X-direction that is located relatively close to the first chip side surface 20A. In other words, the first cover portion 51 extends over the entirety of the first chip side surface 20A in the Y-direction, so that the sloped surface 51A is sloped toward the substrate head surface 40S as the sloped surface 51A extends away from the first chip side surface 20A. In the example shown in FIG. 6, the sloped surface 51A of the first cover portion 51 has a curved concave shape.

The first cover portion 51 does not project from the chip back surface 20R at the corner 27 of the semiconductor chip 20. At the corner 27, the back surface-side chip side surface 20AB is curved outward as the back surface-side chip side surface 20AB extends toward the chip back surface 20R, so that the first cover portion 51 will not project from the chip back surface 20R. In an example, an end of the first cover portion 51 that is relatively close to the chip back surface 20R is located at the same position as the chip back surface 20R in the Z-direction.

As shown in FIG. 2, in plan view, the first encapsulation resin 50 partially covers the terminal head surface 30S of the substrate terminals 30 that are arranged around the semiconductor chip 20. More specifically, in plan view, the first to fourth cover portions 51 to 54 partially cover the terminal head surface 30S of the substrate terminals 30 that are arranged around the semiconductor chip 20. As shown in FIG. 6, the first cover portion 51 of the first encapsulation resin 50 covers a part of the terminal head surface 30S of the heat dissipation terminal 30P that is located relatively close to the first chip side surface 20A of the semiconductor chip 20. In an example, the first cover portion 51 covers the head surface wiring portion 32 and part of the through-wiring portion 31 of the heat dissipation terminal 30P. In an example, the first cover portion 51 does not cover the through-wiring portion 31 of the other substrate terminal 30 that is not the heat dissipation terminal 30P, while covering the head surface wiring portion 32 of the other substrate terminal 30.

### Heat Dissipation Member

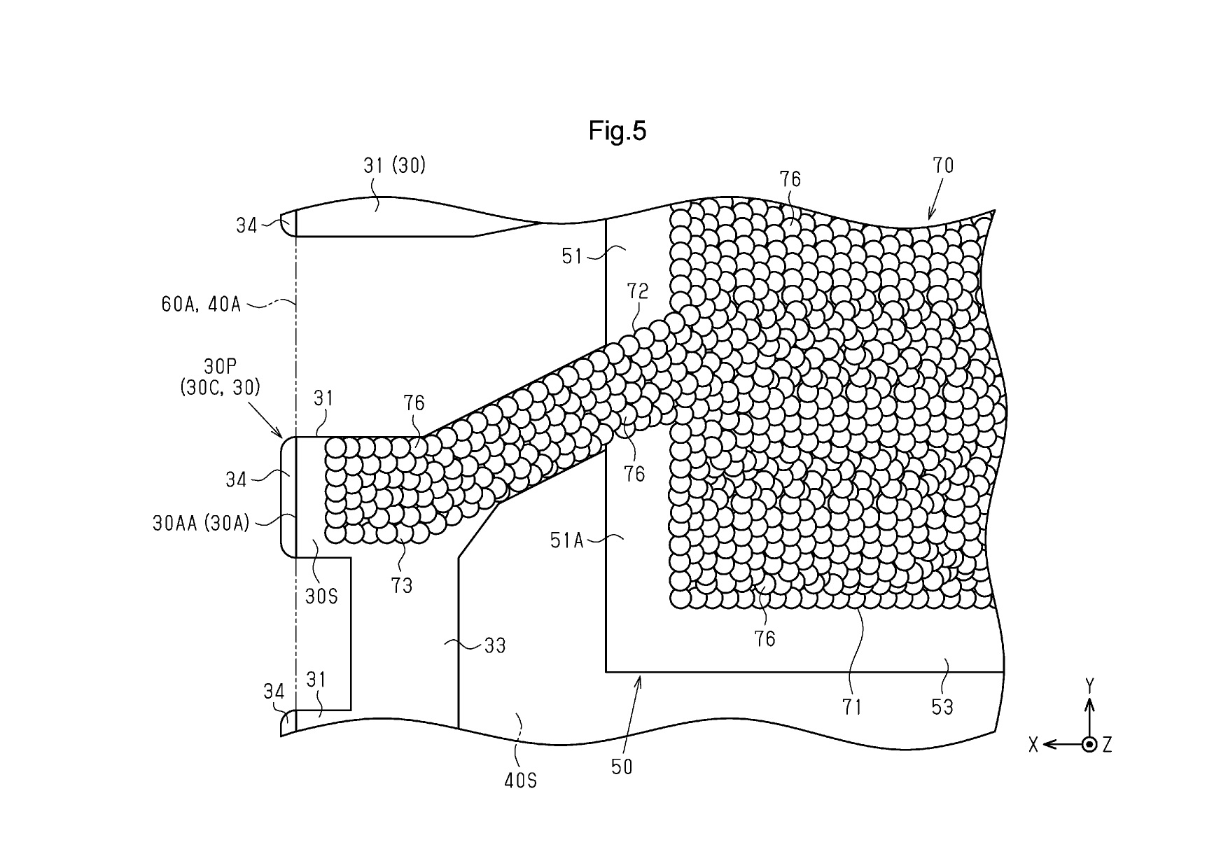

The structure of the heat dissipation member 70 will now be described with reference to FIGS. 2 and 4 to 6. FIG. 5 is an enlarged schematic plan view of part of the heat dissipation member 70 and its surroundings.

As shown in FIGS. 2 and 4, the heat dissipation member 70 is in contact with each of the chip back surface 20R of the semiconductor chip 20, the encapsulation head surface 50S of the first encapsulation resin 50, and the terminal head surface 30S of the heat dissipation terminal 30P.

The heat dissipation member 70 is configured so that heat of the semiconductor chip 20 is transferred from the semiconductor chip 20 to the heat dissipation terminal 30P. The heat dissipation member 70 has a higher thermal conductivity than the semiconductor substrate 21 of the semiconductor chip 20. The heat dissipation member 70 has a higher thermal conductivity than the second encapsulation resin 60. The heat dissipation member 70 has a higher thermal conductivity than the first encapsulation resin 50. The heat dissipation member 70 is formed from, for example, a metal material. In an example, the material of the heat dissipation member 70 includes at least one of Au, Cu, and Ag. In an example, the heat dissipation member 70 has a thickness in a range of 5 μm to 30 μm, inclusive. The thickness of the heat dissipation member 70 may be changed.

As shown in FIGS. 2 and 4, the heat dissipation member 70 includes a first heat dissipation portion 71 that is in contact with the chip back surface 20R, a second heat dissipation portion 72 that is in contact with the first cover portion 51, and a third heat dissipation portion 73 that is in contact with the terminal head surface 30S of the heat dissipation terminal 30P. In an example, the first heat dissipation portion 71, the second heat dissipation portion 72, and the third heat dissipation portion 73 are integrated with each other.

The first heat dissipation portion 71 may be formed to cover the entire heat generation portion 25 of the semiconductor chip 20 in plan view. In the present embodiment, the first heat dissipation portion 71 extends over the entirety of the chip back surface 20R in plan view. In other words, the heat dissipation member 70 extends over the entire chip back surface 20R. The first heat dissipation portion 71 is thinner than the semiconductor chip 20.

The second heat dissipation portion 72 is in contact with the sloped surface 51A of the first cover portion 51. The second heat dissipation portion 72 follows the curved concave shape of the sloped surface 51A. That is, the second heat dissipation portion 72 has a curved concave shape. The second heat dissipation portion 72 is formed on part of the sloped surface 51A in the Y-direction. The second heat dissipation portion 72 extends over the entirety of the sloped surface 51A in the X-direction. The second heat dissipation portion 72 formed on the sloped surface 51A is located at the same position as the heat dissipation terminal 30P in the Y-direction.

In plan view, the width of the second heat dissipation portion 72 is equal to the width of the head surface wiring portion 32 of the heat dissipation terminal 30P. The width of the second heat dissipation portion 72 refers to the dimension of the second heat dissipation portion 72 in a direction orthogonal to the direction in which the second heat dissipation portion 72 extends in plan view. The width of the head surface wiring portion 32 refers to the dimension of the head surface wiring portion 32 in a direction orthogonal to the direction in which the head surface wiring portion 32 extends in plan view. The width of the second heat dissipation portion 72 may be changed. In an example, the width of the second heat dissipation portion 72 may be greater than the width of the head surface wiring portion 32 of the heat dissipation terminal 30P.

The third heat dissipation portion 73 is in contact with at least the terminal head surface 30S that corresponds to one of the two through-wiring portions 31 of the heat dissipation terminal 30P. In an example, the third heat dissipation portion 73 extends over most of the terminal head surface 30S of one of the two through-wiring portions 31.

As shown in FIG. 5, in the present embodiment, the heat dissipation member 70 is formed by a conductive ink. The conductive ink may include, for example, Au or Ag. The heat dissipation member 70 is formed by, for example, ink-jet printing. As shown in FIG. 5, the heat dissipation member 70, which is formed by ink-jet printing, includes a large number of dots 76. The dots 76 are circular in plan view. Adjacent dots 76 partially overlap each other, such that the large number of dots 76 form the heat dissipation member 70.

The heat dissipation member 70 includes a heat dissipation head surface 70S, which is formed by a large number of dots 76. The heat dissipation head surface 70S has irregularities. That is, adjacent dots 76 partially overlap each other, such that the heat dissipation head surface 70S has projections and depressions.

### Semiconductor Device Manufacturing Method

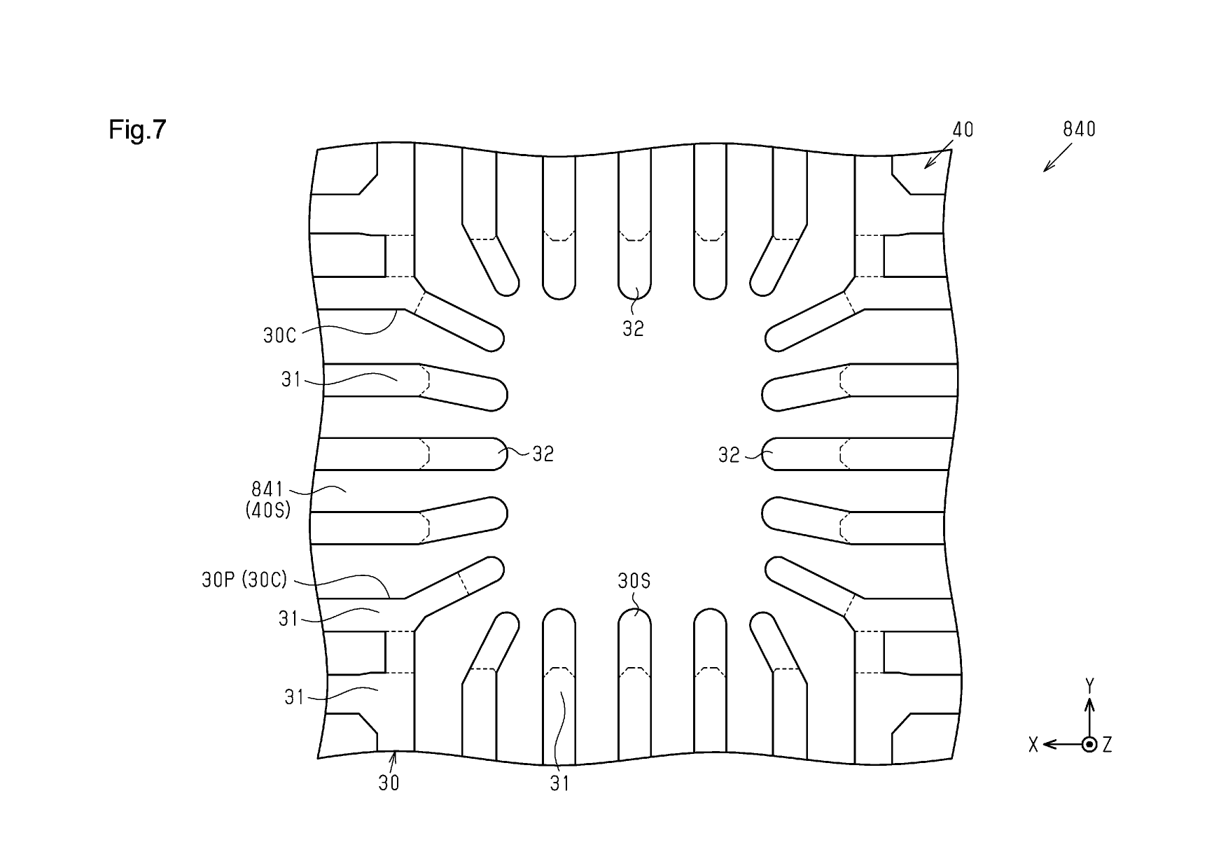

An example of a method for manufacturing the semiconductor device 10 will now be described with reference to FIGS. 7 to 11.

The method for manufacturing the semiconductor device 10 mainly includes a step of preparing the substrate 40, a step of mounting the semiconductor chip 20 on the substrate terminals 30, a step of forming the first encapsulation resin 50, a step of forming the heat dissipation member 70, a step of forming the second encapsulation resin 60, and a step of singulation.

FIG. 7 illustrates an example of the step of preparing the substrate 40.

In the step of preparing the substrate 40, a substrate base material 840 is prepared. FIG. 7 is a schematic plan view showing the structure of the substrate base material 840. The substrate base material 840 includes the substrate 40 and the substrate terminals 30. The substrate terminals 30 are connected to a frame (not shown) surrounding the substrate terminals 30. In other words, the substrate terminals 30 and the frame may be integrally formed as an integrated structure, such as a lead frame. The substrate base material 840 may include multiple pieces of substrates 40 and multiple sets of substrate terminals 30 to obtain multiple pieces of semiconductor devices 10. FIG. 7 shows a portion of the substrate base material 840 that corresponds to a single substrate 40.

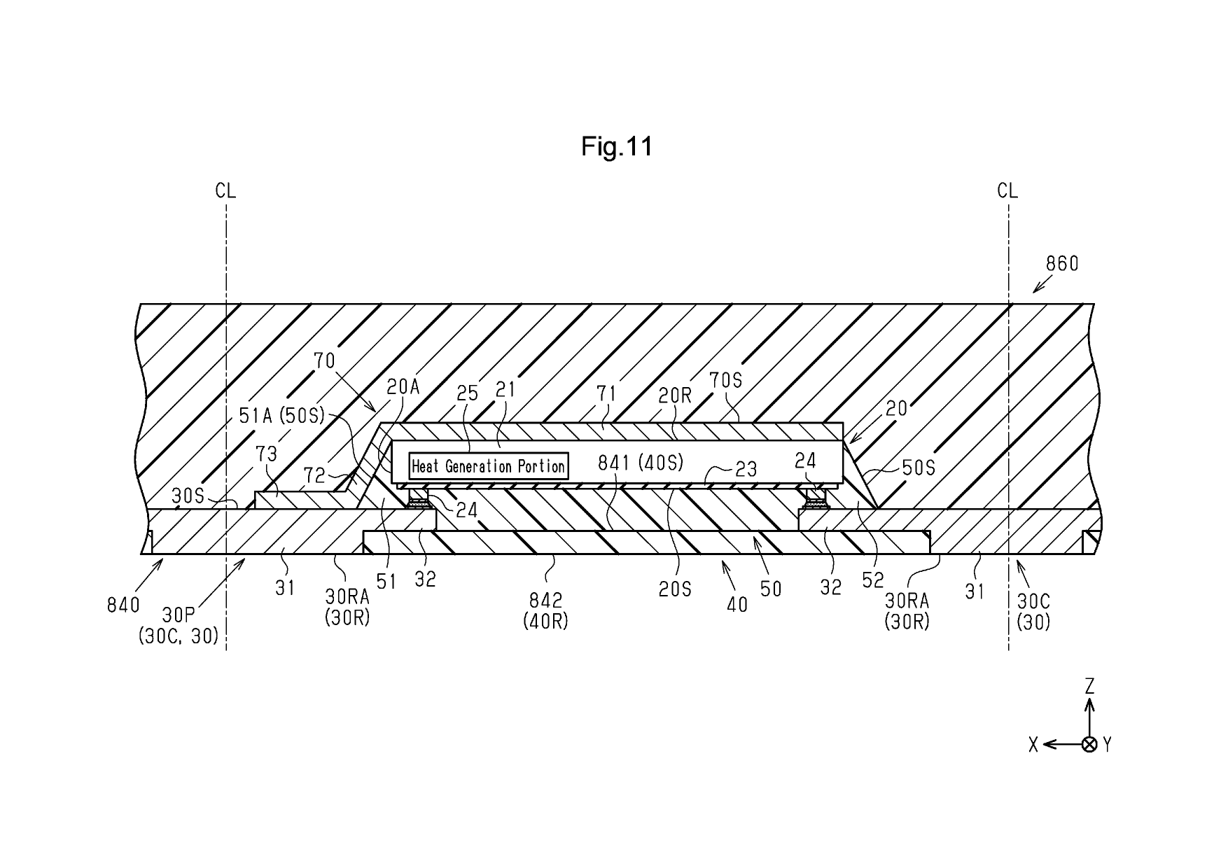

The substrate base material 840 has a flat plate shape and has a thickness in the Z-direction. The substrate base material 840 includes a substrate head surface 841 and a substrate back surface 842 (refer to FIG. 11) that face away from each other in the Z-direction. The substrate head surface 841 defines the substrate head surface 40S of multiple substrates 40. The substrate back surface 842 defines the substrate back surface 40R (refer to FIG. 11) of the multiple substrates 40.

The substrate terminals 30 are formed at portions of the substrate base material 840 that correspond to the multiple substrates 40. In other words, each substrate 40 includes substrate terminals 30 that extend through the substrate 40 in the Z-direction, which is the thickness-wise direction of the substrate 40. Each substrate terminal 30 includes the terminal head surface 30S exposed from the substrate head surface 40S, and the terminal back surface 30R (refer to FIG. 11) exposed from the substrate back surface 40R.

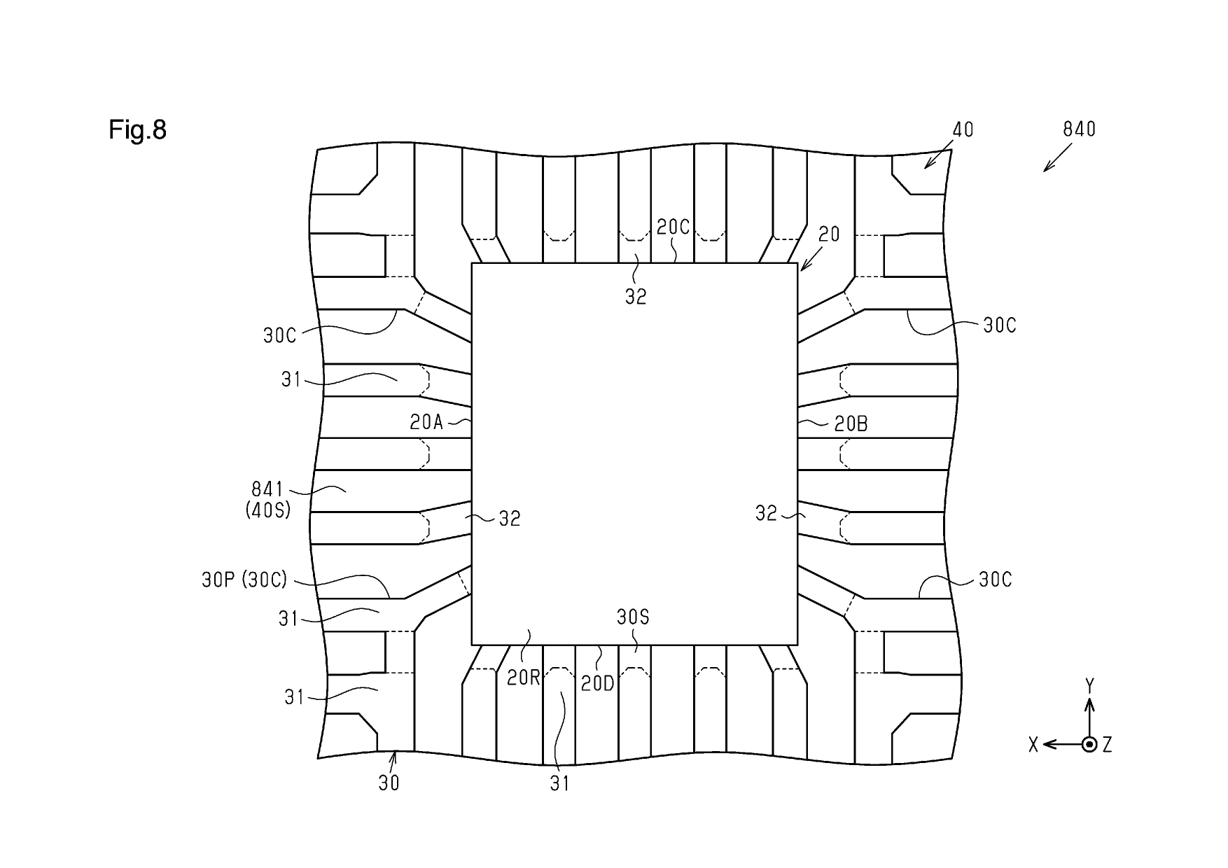

FIG. 8 illustrates an example of the step for mounting the semiconductor chip 20 on the substrate terminals 30. FIG. 8 is a schematic plan view showing the structure of the semiconductor chip 20 and part of the substrate base material 840.

In the step of mounting the semiconductor chip 20 on the substrate terminals 30, the conductive bonding material SD (refer to FIG. 6) is first applied to the barrier layer 35 (refer to FIG. 6) of the substrate terminals 30. Then, the chip terminals 24 (refer to FIG. 6) of the semiconductor chip 20 are arranged on the conductive bonding material SD, which is formed on the substrate terminals 30. Subsequently, the conductive bonding material SD is melted and then solidified by, for example, reflow soldering. As a result, the chip terminals 24 are bonded to the substrate terminals 30 by the conductive bonding material SD. This electrically connects the chip terminals 24 to the substrate terminals 30.

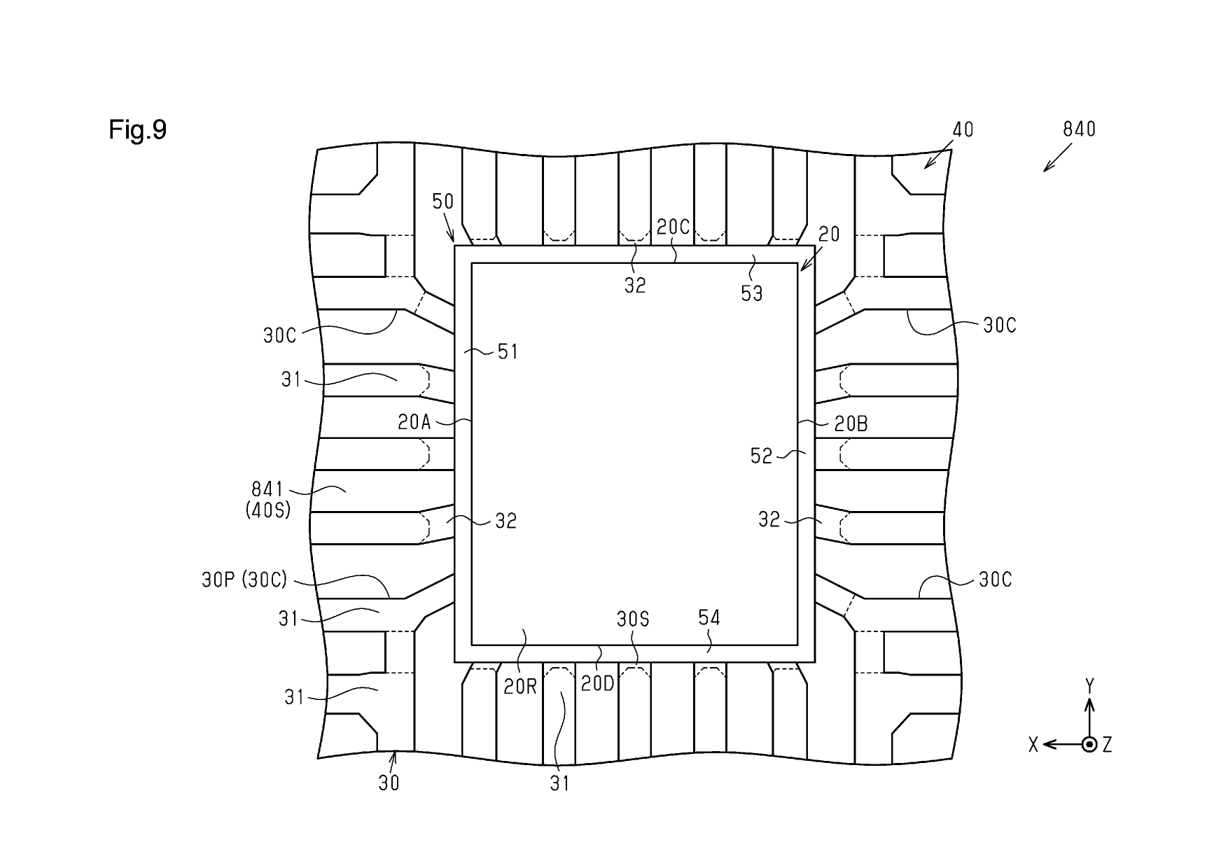

FIG. 9 illustrates an example of the step for forming the first encapsulation resin 50. FIG. 9 is a schematic plan view showing the structure of the substrate base material 840, the semiconductor chip 20, and the first encapsulation resin 50.

In the step of forming the first encapsulation resin 50, the gap between the substrate head surface 841 (40S) of the substrate base material 840 (substrate 40) and the semiconductor chip 20 is filled with a resin material by, for example, resin molding. In this case, the first encapsulation resin 50 is formed to cover the chip head surface 20S (refer to FIG. 11) and the first to fourth chip side surfaces 20A to 20D of the semiconductor chip 20.

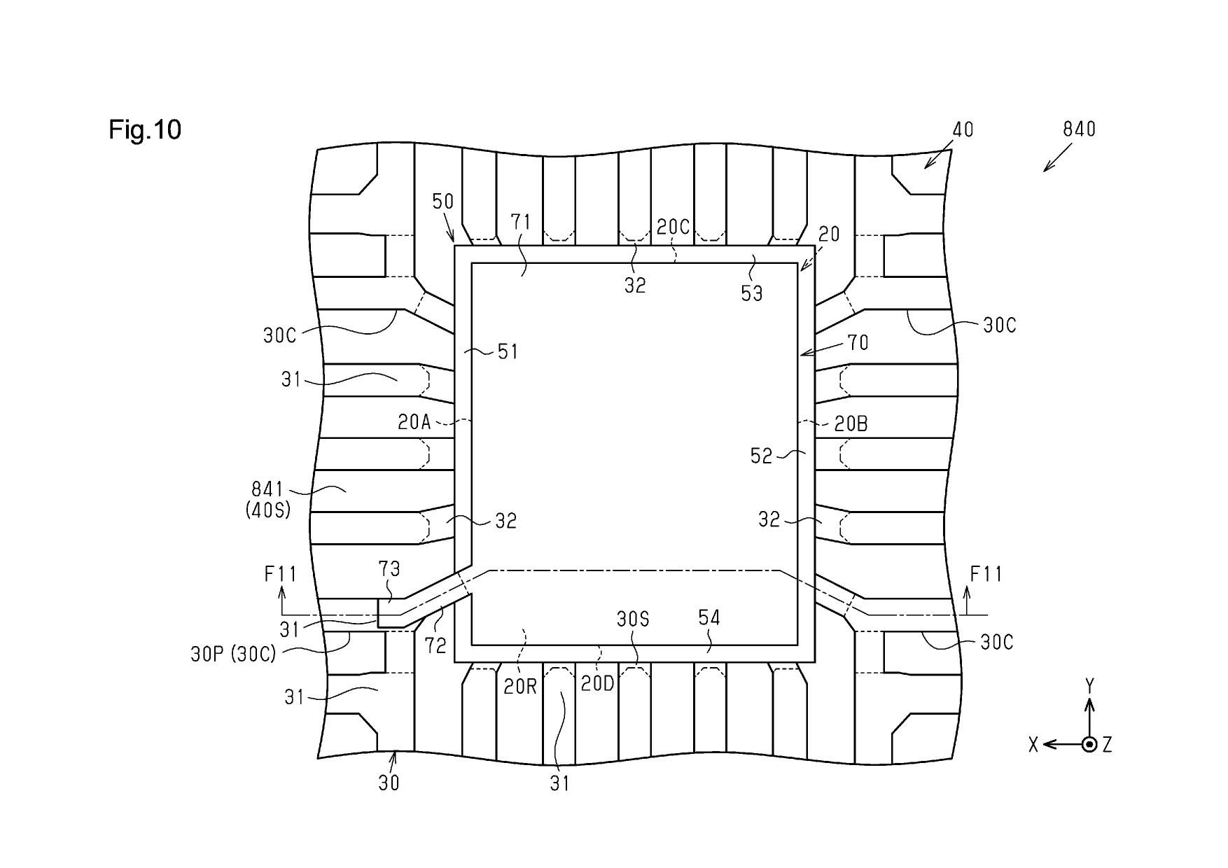

FIG. 10 illustrates an example of the step for forming the heat dissipation member 70. FIG. 10 is a schematic plan view showing the structure of the substrate base material 840, the semiconductor chip 20, the first encapsulation resin 50, and the heat dissipation member 70.

In the step of forming the heat dissipation member 70, the heat dissipation member 70 is formed by ink-jet printing. More specifically, during ink-jet printing, a conductive ink is discharged onto the chip back surface 20R of the semiconductor chip 20, the first cover portion 51 of the first encapsulation resin 50, and the terminal head surface 30S of the heat dissipation terminal 30P. As a result, the heat dissipation member 70 is in contact with each of the chip back surface 20R, the encapsulation head surface 50S of the first encapsulation resin 50, and the terminal head surface 30S of the heat dissipation terminal 30P.

FIG. 11 illustrates an example of the step for forming the second encapsulation resin 60. FIG. 11 is a schematic cross-sectional view showing the structure of the substrate base material 840, the semiconductor chip 20, the first encapsulation resin 50, the heat dissipation member 70, and the second encapsulation resin 60.

The step of forming the second encapsulation resin 60 is performed after the step of forming the heat dissipation member 70. In the step of forming the second encapsulation resin 60, a resin layer 860 is formed on the substrate base material 840 to cover the semiconductor chip 20, the first encapsulation resin 50, and the heat dissipation member 70 by, for example, transfer molding. The resin layer 860 includes multiple pieces of the second encapsulation resin 60 (refer to FIG. 4). The resin layer 860 and the first encapsulation resin 50 are formed from different materials. The material of the first encapsulation resin 50 has a higher thermal conductivity than that of the resin layer 860. In an example, the material of the first encapsulation resin 50 has a higher thermal conductivity than air.

In the singulating step, the resin layer 860, the substrate base material 840, and the substrate terminals 30 are cut along cutting lines CL shown in FIG. 11 by, for example, dicing. This obtains multiple pieces of the second encapsulation resin 60 and the substrates 40 (refer to FIG. 4). The terminal side surfaces 30A (refer to FIG. 4) of the through-wiring portions 31 of the substrate terminals 30 are exposed from the first to fourth substrate side surfaces 40A to 40D (refer to FIG. 2) of each substrate 40.

Although not shown in the drawings, the method for manufacturing the semiconductor device 10 includes a step of forming the plating layer 34 (refer to FIG. 4). The plating layer 34 is formed by, for example, electroless plating. As a result, the plating layer 34 is formed on the exposed surface 30RA of the terminal back surface 30R and the exposed side surface 30AA of each substrate terminal 30, which are exposed from the first encapsulation resin 50. The semiconductor device 10 is manufactured by the above-described procedure.

The manufacturing steps of the semiconductor device 10 may be changed. In an example, dicing may be performed along the cutting lines CL shown in FIG. 11 to cut the resin layer 860 to an intermediate position in the Z-direction, while cutting through the substrate base material 840 and the substrate terminals 30. This step forms the terminal side surface 30A (exposed side surface 30AA). Accordingly, the plating layer 34 may be formed on the exposed surface 30RA and the exposed side surface 30AA before separating the resin layer 860, that is, before singulation. Then, dicing may be performed again to cut through the resin layer 860. The semiconductor device 10 may be manufactured by such a procedure.

### Operation of the Embodiment

The operation of the semiconductor device 10 in accordance with the present embodiment will now be described.

When the semiconductor device 10 is mounted on, for example, a wiring board (not shown), heat of the semiconductor chip 20 is transferred through the chip terminals 24 and the substrate terminals 30 to the wiring board. The semiconductor device 10 of the present embodiment includes the heat dissipation member 70 that is in contact with the chip back surface 20R of the semiconductor chip 20, the encapsulation head surface 50S of the first encapsulation resin 50, and the terminal head surface 30S of the heat dissipation terminal 30P. Therefore, heat of the semiconductor chip 20 is transferred through the heat dissipation member 70 and the heat dissipation terminal 30P to the wiring board. In this manner, in the semiconductor device 10 of the present embodiment, heat of the semiconductor chip 20 is conducted to the wiring board through multiple paths, namely, a first path including the chip terminals 24 and the substrate terminals 30, and a second path including the heat dissipation member 70 and the heat dissipation terminal 30P. This facilitates heat dissipation from the semiconductor chip 20 to the wiring board, and therefore the temperature of the semiconductor chip 20 will not become excessively high.

### Advantages of the Embodiment

The semiconductor device 10 of the present embodiment has the following advantages.

(1) The semiconductor device 10 includes the substrate 40, the substrate terminals 30, the semiconductor chip 20, and the first encapsulation resin 50. The substrate 40 includes the substrate head surface 40S, and the substrate back surface 40R opposite to the substrate head surface 40S. The substrate terminals 30 extend through the substrate 40 in the Z-direction. The substrate terminals 30 each include the terminal head surface 30S exposed from the substrate head surface 40S, and the terminal back surface 30R including a portion exposed from the substrate back surface 40R. The semiconductor chip 20 includes the chip head surface 20S facing the terminal head surface 30S, the chip back surface 20R opposite to the chip head surface 20S, the first to fourth chip side surfaces 20A to 20D connecting the chip head surface 20S and the chip back surface 20R, and the chip terminals 24 formed on the chip head surface 20S and electrically connected to the terminal head surface 30S of the substrate terminals 30. The first encapsulation resin 50 covers the chip head surface 20S and the chip side surfaces 20A to 20D of the semiconductor chip 20. The substrate terminals 30 include the heat dissipation terminal 30P that has a portion located outward from the semiconductor chip 20 in plan view. The semiconductor device 10 includes the heat dissipation member 70 that is in contact with each of the chip back surface 20R, the encapsulation head surface 50S of the first encapsulation resin 50, and the terminal head surface 30S of the heat dissipation terminal 30P.

With this structure, the heat conduction paths of the semiconductor chip 20 include a path extending through the heat dissipation member 70 to the heat dissipation terminal 30P, and a path extending through the chip terminals 24 to the substrate terminals 30. These heat conduction paths of the semiconductor chip 20 improve the heat dissipation performance of the semiconductor device 10.

(2) The heat dissipation member 70 is formed by a conductive ink.

With this structure, the heat dissipation member 70 can be formed by ink-jet printing. This reduces manufacturing costs of the heat dissipation member 70 as compared to when a heat dissipation member is formed by, for example, stamping a metal plate. In addition, since ink-jet printing is performed, the layout of printed regions can be readily changed. Accordingly, the shape of heat dissipation member 70 can be readily changed.

(3) The heat dissipation member 70 extends over the entirety of the chip back surface 20R of the semiconductor chip 20.

With this structure, heat of the semiconductor chip 20 is readily transferred from the chip back surface 20R to the heat dissipation member 70. This improves the heat dissipation performance of the semiconductor device 10.

(4) The first encapsulation resin 50 fills the gap between the chip head surface 20S of the semiconductor chip 20 and the substrate head surface 40S of the substrate 40. The first encapsulation resin 50 and the second encapsulation resin 60 are formed from different materials.

With this structure, a material that is suitable for desired characteristics (e.g., heat dissipation performance) of the first encapsulation resin 50 and a material that is suitable for desired characteristics (e.g., encapsulation performance) of the second encapsulation resin 60 may be selected independently.

(5) The first encapsulation resin 50 has a higher thermal conductivity than the second encapsulation resin 60.

With this structure, heat of the semiconductor chip 20 is readily transferred through the first encapsulation resin 50 to the substrate terminals 30 of the substrate 40. In addition, heat of the heat dissipation member 70 is readily transferred from a portion of the heat dissipation member 70, which is in contact with the encapsulation head surface 50S of the first encapsulation resin 50, through the first encapsulation resin 50 to the substrate terminals 30. This improves the heat dissipation performance of the semiconductor device 10.

(6) The first encapsulation resin 50 has a higher thermal conductivity than air.

This structure enhances the above-described advantage (5). In a comparative structure in which the second encapsulation resin 60 is not formed, and a metal plate is in contact with each of a chip back surface of a semiconductor chip and a substrate terminal (hereafter, “the comparative structure”), a first portion in which the metal plate is joined to the chip back surface and a second portion in which the metal plate is connected to the substrate terminal are connected by a third portion that is hollow. In contrast, in the heat dissipation member 70 of the present embodiment, the first heat dissipation portion 71, which is in contact with the chip back surface 20R, and the third heat dissipation portion 73, which is in contact with the heat dissipation terminal 30P, are connected by the second heat dissipation portion 72 that is in contact with the first encapsulation resin 50. This facilitates heat dissipation from the second heat dissipation portion 72 to the first encapsulation resin 50, as compared to the above-described comparative structure.

(7) In plan view, the first encapsulation resin 50 partially covers the substrate terminals 30 and the heat dissipation terminal 30P that are arranged around the semiconductor chip 20.

With this structure, the semiconductor chip 20 is connected to the substrate terminals 30 and the heat dissipation terminal 30P by the first encapsulation resin 50. This facilitates heat transfer from the semiconductor chip 20 through the first encapsulation resin 50 to the substrate terminals 30 and the heat dissipation terminal 30P.

(8) The semiconductor chip 20 includes the heat generation portion 25, and the first chip side surface 20A that faces the X-direction. The first chip side surface 20A is part of the chip side surfaces. The heat generation portion 25 is disposed in the semiconductor chip 20 and located relatively close to the first chip side surface 20A in the X-direction. In plan view, the heat dissipation terminal 30P is located adjacent to the first chip side surface 20A in the X-direction. The first encapsulation resin 50 includes the first cover portion 51 that covers the first chip side surface 20A. The heat dissipation member 70 is in contact with the first cover portion 51.

With this structure, the heat conduction path extending from the heat generation portion 25 to the heat dissipation terminal 30P is relatively short. This facilitates heat dissipation from the heat generation portion 25 to the heat dissipation terminal 30P, thereby improving the heat dissipation performance of the semiconductor device 10.

(9) The first cover portion 51 covers the entirety of the first chip side surface 20A in the Z-direction.

With this structure, a portion (first heat dissipation portion 71) of the heat dissipation member 70 that is in contact with the chip back surface 20R of the semiconductor chip 20 is smoothly connected to a portion (second heat dissipation portion 72) of the heat dissipation member 70 that is in contact with the encapsulation head surface 50S of the first encapsulation resin 50. Therefore, a breakage will not be formed between the first heat dissipation portion 71 and the second heat dissipation portion 72 when the heat dissipation member 70 is, for example, ink-jet printed.

(10) The first cover portion 51 includes the sloped surface 51A that is sloped toward the terminal head surface 30S of the heat dissipation terminal 30P as the sloped surface 51A extends away from the first chip side surface 20A. The sloped surface 51A is part of the encapsulation head surface 50S of the first encapsulation resin 50. The sloped surface 51A is connected to the corner 27 formed by the chip back surface 20R and the first chip side surface 20A.

With this structure, a portion (first heat dissipation portion 71) of the heat dissipation member 70 that is in contact with the chip back surface 20R of the semiconductor chip 20 is further smoothly connected to a portion (second heat dissipation portion 72) of the heat dissipation member 70 that is in contact with the encapsulation head surface 50S of the first encapsulation resin 50. Therefore, a breakage will not be formed between the first heat dissipation portion 71 and the second heat dissipation portion 72 when the heat dissipation member 70 is, for example, ink-jet printed.

(11) The sloped surface 51A of the first cover portion 51 has a curved concave shape. The heat dissipation member 70 includes a portion that is in contact with the sloped surface 51A, the portion following the curved concave shape of the sloped surface 51A.

With this structure, the distance from a portion (second heat dissipation portion 72) of the heat dissipation member 70 that is in contact with the sloped surface 51A to the substrate 40 (substrate terminals 30) in the Z-direction is relatively short. Accordingly, the heat conduction path extending from the second heat dissipation portion 72 to the substrate 40 (substrate terminals 30) is relatively short.

(12) The first cover portion 51 covers a portion of the terminal head surface 30S of the heat dissipation terminal 30P that is located relatively close to the first chip side surface 20A.

With this structure, a portion (second heat dissipation portion 72) of the heat dissipation member 70 that is in contact with the encapsulation head surface 50S of the first encapsulation resin 50 is smoothly connected to a portion (third heat dissipation portion 73) of the heat dissipation member 70 that is in contact with the terminal head surface 30S of the heat dissipation terminal 30P. Therefore, a breakage will not be formed between the second heat dissipation portion 72 and the third heat dissipation portion 73 when the heat dissipation member 70 is, for example, ink-jet printed. In addition, the first cover portion 51 covers a portion of the terminal head surface 30S that is located relatively close to the first chip side surface 20A, so that the heat dissipation member 70 is in contact with the terminal head surface 30S of the heat dissipation terminal 30P while minimizing the length of the second heat dissipation portion 72. As a result, the heat conduction path extending from the semiconductor chip 20 through the heat dissipation member 70 to the heat dissipation terminal 30P is relatively short.

(13) The substrate terminals 30 each include the through-wiring portion 31 that extends through the substrate 40 in the Z-direction. The heat dissipation member 70 is in contact with the terminal head surface 30S that corresponds to the through-wiring portion 31 of the heat dissipation terminal 30P.

With this structure, when the semiconductor device 10 is mounted on, for example, a wiring board (not shown), heat of the heat dissipation member 70 is readily transferred through the through-wiring portion 31 to the wiring board. This improves the heat dissipation performance of the semiconductor device 10.

(14) The heat dissipation member 70 has a thickness in a range of 5 μm to 30 μm, inclusive.

With this structure, the semiconductor device 10 has a relatively low profile as compared to a structure in which a metal plate is bonded to the chip back surface 20R of the semiconductor chip 20 by, for example, solder paste.

(15) The heat dissipation member 70 includes the heat dissipation head surface 70S. The heat dissipation head surface 70S has irregularities.

With this structure, the second encapsulation resin 60 catches the irregularities of the heat dissipation head surface 70S, thereby improving the adhesion between the heat dissipation member 70 and the second encapsulation resin 60 by, for example, an anchor effect.

(16) The heat dissipation member 70 includes the first heat dissipation portion 71 that is in contact with the chip back surface 20R, the second heat dissipation portion 72 that is in contact with the first cover portion 51, and the third heat dissipation portion 73 that is in contact with the terminal head surface 30S of the heat dissipation terminal 30P. The first heat dissipation portion 71, the second heat dissipation portion 72, and the third heat dissipation portion 73 are integrated with each other.

With this structure, heat is readily transferred from the first heat dissipation portion 71 through the second heat dissipation portion 72 to the third heat dissipation portion 73, as compared to a structure in which the first heat dissipation portion 71, the second heat dissipation portion 72, and the third heat dissipation portion 73 are separate elements. This improves the heat dissipation performance of the semiconductor device 10.

(17) The heat dissipation terminal 30P includes the terminal back surface 30R that faces away from the terminal head surface 30S, and the terminal side surface 30A that connects the terminal head surface 30S and the terminal back surface 30R. At least part of the terminal side surfaces 30A of the heat dissipation terminal 30P is exposed from the substrate 40.

With this structure, the heat dissipation terminal 30P readily dissipates heat to the outside of the semiconductor device 10, as compared to a structure in which the substrate 40 covers the entire terminal side surface 30A of the heat dissipation terminal 30P. This improves the heat dissipation performance of the semiconductor device 10.

(18) The plating layer 34 is disposed on the terminal side surface 30A of the heat dissipation terminal 30P that is exposed from the substrate 40.

With this structure, when the semiconductor device 10 is mounted on a wiring board (not shown) by, for example, solder paste, the solder paste is in contact with the plating layer 34 formed on the terminal side surface 30A. This facilitates heat dissipation from the heat dissipation terminal 30P to the wiring board.

(19) The method for manufacturing the semiconductor device 10 includes preparing the substrate 40. The substrate 40 includes the substrate head surface 40S, the substrate back surface 40R opposite to the substrate head surface 40S, and the substrate terminals 30. The substrate terminals 30 extend through the substrate 40 in the Z-direction. The substrate terminals 30 each include the terminal head surface 30S exposed from the substrate head surface 40S, and the terminal back surface 30R including a portion exposed from the substrate back surface 40R. The method further includes electrically connecting the chip terminals 24 of the semiconductor chip 20 to the substrate terminals 30. The semiconductor chip 20 includes the chip head surface 20S facing the terminal head surface 30S, the chip back surface 20R opposite to the chip head surface 20S, the first to fourth chip side surfaces 20A to 20D connecting the chip head surface 20S and the chip back surface 20R, and the chip terminals 24 formed on the chip head surface 20S. The method further includes forming the first encapsulation resin 50 to cover the chip head surface 20S and the chip side surfaces 20A to 20D of the semiconductor chip 20. The substrate terminals 30 include the heat dissipation terminal 30P that has a portion located outward from the semiconductor chip 20 in plan view. The method for manufacturing the semiconductor device 10 further includes forming the heat dissipation member 70 to be in contact with each of the chip back surface 20R, the encapsulation head surface 50S of the first encapsulation resin 50, and the terminal head surface 30S of the heat dissipation terminal 30P.

With this structure, the heat conduction paths of the semiconductor chip 20 include a path extending through the heat dissipation member 70 to the heat dissipation terminal 30P, and a path extending through the chip terminals 24 to the substrate terminals 30. These heat conduction paths of the semiconductor chip 20 improve the heat dissipation performance of the semiconductor device 10.

(20) The heat dissipation member 70 is formed by ink-jet printing.

With this structure, manufacturing costs of the heat dissipation member 70 may be reduced as compared to when a heat dissipation member is formed by, for example, stamping a metal plate. In addition, the layout of printed regions can be readily changed by ink-jet printing, so that the shape of heat dissipation member 70 can be readily changed.

### Modified Examples

The above embodiment may be modified as described below. The modified examples described below may be combined as long as there is no technical contradiction.

The location of the heat generation portion 25 of the semiconductor chip 20 in plan view may be changed. In an example, the heat generation portion 25 may be located at a central position of the semiconductor chip 20 in plan view.

The terminal side surface 30A of the substrate terminals 30 may be entirely covered by the substrate 40. In this case, the plating layer 34 is formed on only the exposed surface 30RA of the terminal back surface 30R. Similarly, the terminal side surface 30A of the heat dissipation terminal 30P may be entirely covered by the substrate 40.

The number of substrate terminals 30 may be changed.

The plating layer 34 does not have to be formed on the exposed surface 30RA of the substrate terminals 30.

The heat dissipation terminal 30P does not have to be the corner terminal 30C of the substrate terminals 30. The heat dissipation terminal 30P may be the substrate terminal 30 that is located at, for example, a central position of the substrate 40 in the Y-direction.

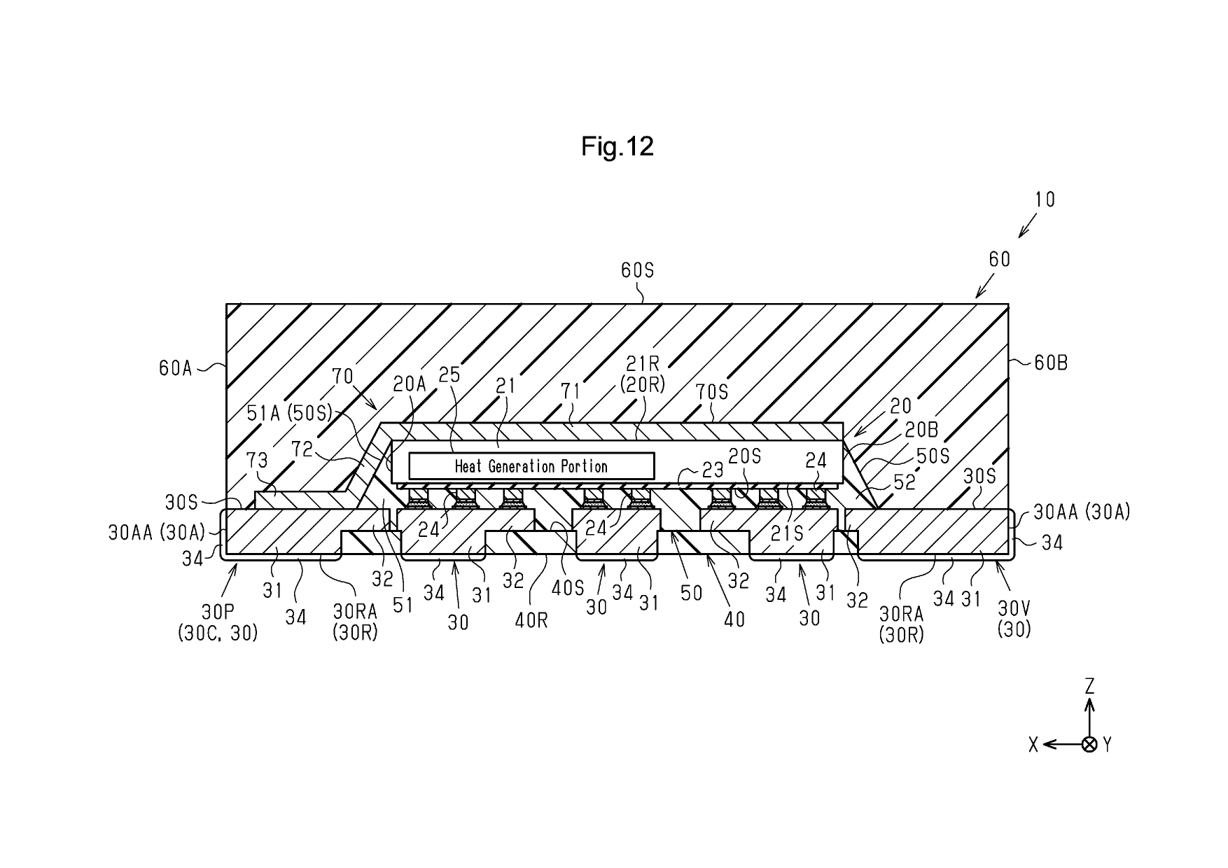

The heat dissipation terminal 30P does not have to be electrically connected to the semiconductor chip 20. That is, the heat dissipation terminal 30P may be electrically floating. FIG. 12 is a schematic cross-sectional view showing an example of the structure of the semiconductor device 10 that includes an electrically-floating heat dissipation terminal 30P.

As shown in FIG. 12, the heat dissipation terminal 30P is entirely located closer to the first encapsulation side surface 60A of the second encapsulation resin 60 than the semiconductor chip 20 is. That is, the heat dissipation terminal 30P does not include a portion that overlaps the semiconductor chip 20 in plan view. In the example shown in FIG. 12, a substrate terminal 30V of the substrate terminals 30 that is located relatively close to the second encapsulation side surface 60B of the second encapsulation resin 60 is electrically floating. The substrate terminal 30V is entirely located closer to the second encapsulation side surface 60B than the semiconductor chip 20 is. That is, the substrate terminal 30V does not include a portion that overlaps the semiconductor chip 20 in plan view.

In the example shown in FIG. 12, multiple (in FIG. 12, three) substrate terminals 30 that are located between the heat dissipation terminal 30P and the substrate terminal 30V are electrically connected to the chip terminals 24 of the semiconductor chip 20. These substrate terminals 30 are electrically connected to the chip terminals 24, respectively. Two of the three substrate terminals 30 that are located relatively close to the heat dissipation terminal 30P overlap the heat generation portion 25 of the semiconductor chip 20 in plan view. One of the three substrate terminals 30 that is located relatively close to the substrate terminal 30V is closer to the substrate terminal 30V than the heat generation portion 25 is in plan view.

The first cover portion 51 of the first encapsulation resin 50 covers a portion of the terminal head surface 30S of the heat dissipation terminal 30P that is located relatively close to the first chip side surface 20A of the semiconductor chip 20. In an example, the first cover portion 51 covers the head surface wiring portion 32 of the heat dissipation terminal 30P. The second cover portion 52 of the first encapsulation resin 50 covers a portion of the terminal head surface 30S of the substrate terminal 30V that is relatively close to the second chip side surface 20B of the semiconductor chip 20.

In the same manner as the embodiment described above, the heat dissipation member 70 is in contact with each of the chip back surface 20R of the semiconductor chip 20, the encapsulation head surface 50S of the first encapsulation resin 50, and the terminal head surface 30S of the heat dissipation terminal 30P. The heat dissipation member 70 is in contact with a portion of the terminal head surface 30S of the heat dissipation terminal 30P that corresponds to both the through-wiring portion 31 and the head surface wiring portion 32. The heat dissipation member 70 has the same structure as the above-described embodiment. The semiconductor device 10 shown in FIG. 12 has advantages similar to advantages (1) to (12) and (14) to (20) of the above-described embodiment.

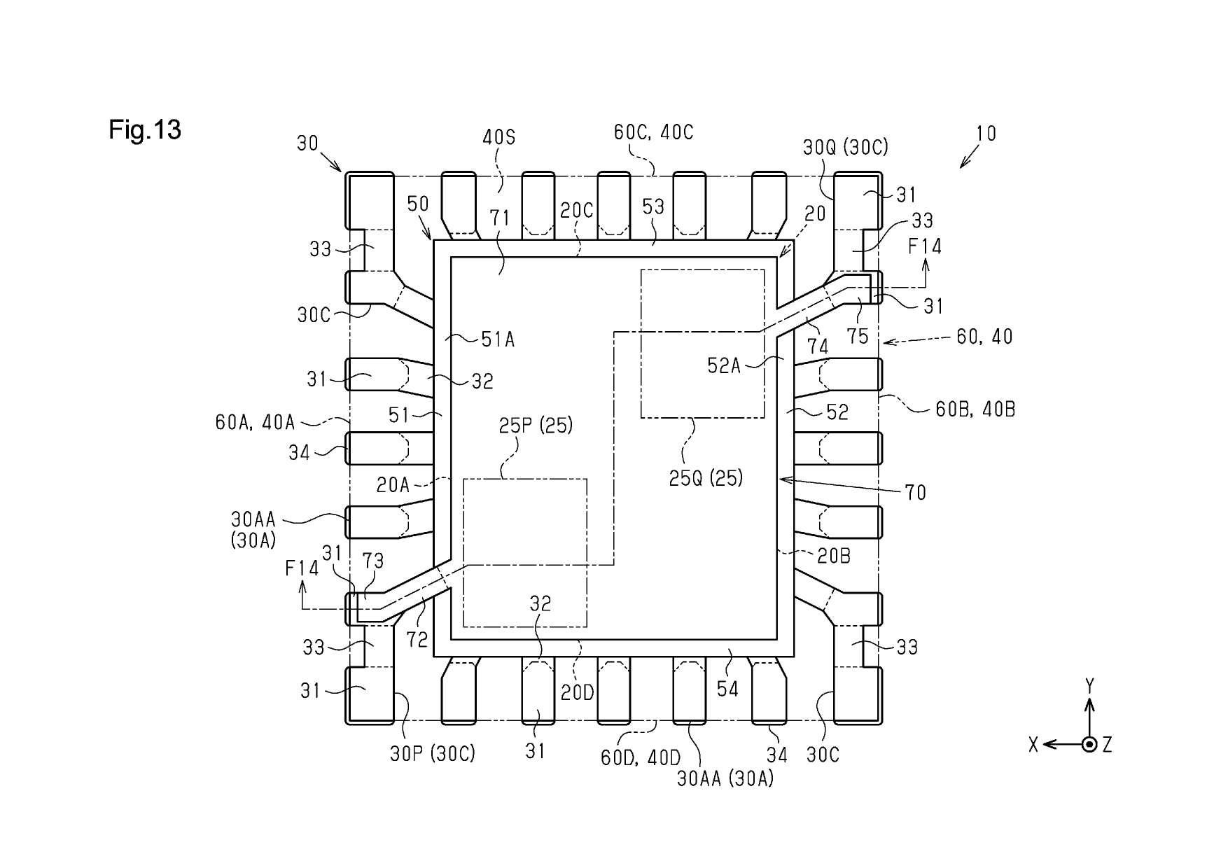

The substrate terminals 30 may include multiple heat dissipation terminals, namely, a first heat dissipation terminal 30P and a second heat dissipation terminal 30Q. In an example, as shown in FIG. 13, the first heat dissipation terminal 30P and the second heat dissipation terminal 30Q may be separately arranged at opposite sides of the semiconductor chip 20 in the X-direction. The first heat dissipation terminal 30P is located at the same position as the heat dissipation terminal 30P of the above-described embodiment. The second heat dissipation terminal 30Q is located relatively close to the second substrate side surface 40B and the third substrate side surface 40C. The first heat dissipation terminal 30P and the second heat dissipation terminal 30Q may have the same functionality and electrically connected to each other. In an example, the first heat dissipation terminal 30P and the second heat dissipation terminal 30Q are ground terminals. At least one of the first heat dissipation terminal 30P and the second heat dissipation terminal 30Q does not have to be electrically connected to the semiconductor chip 20. That is, at least one of the first heat dissipation terminal 30P and the second heat dissipation terminal 30Q may be electrically floating. In an example, both of the first heat dissipation terminal 30P and the second heat dissipation terminal 30Q are electrically floating.

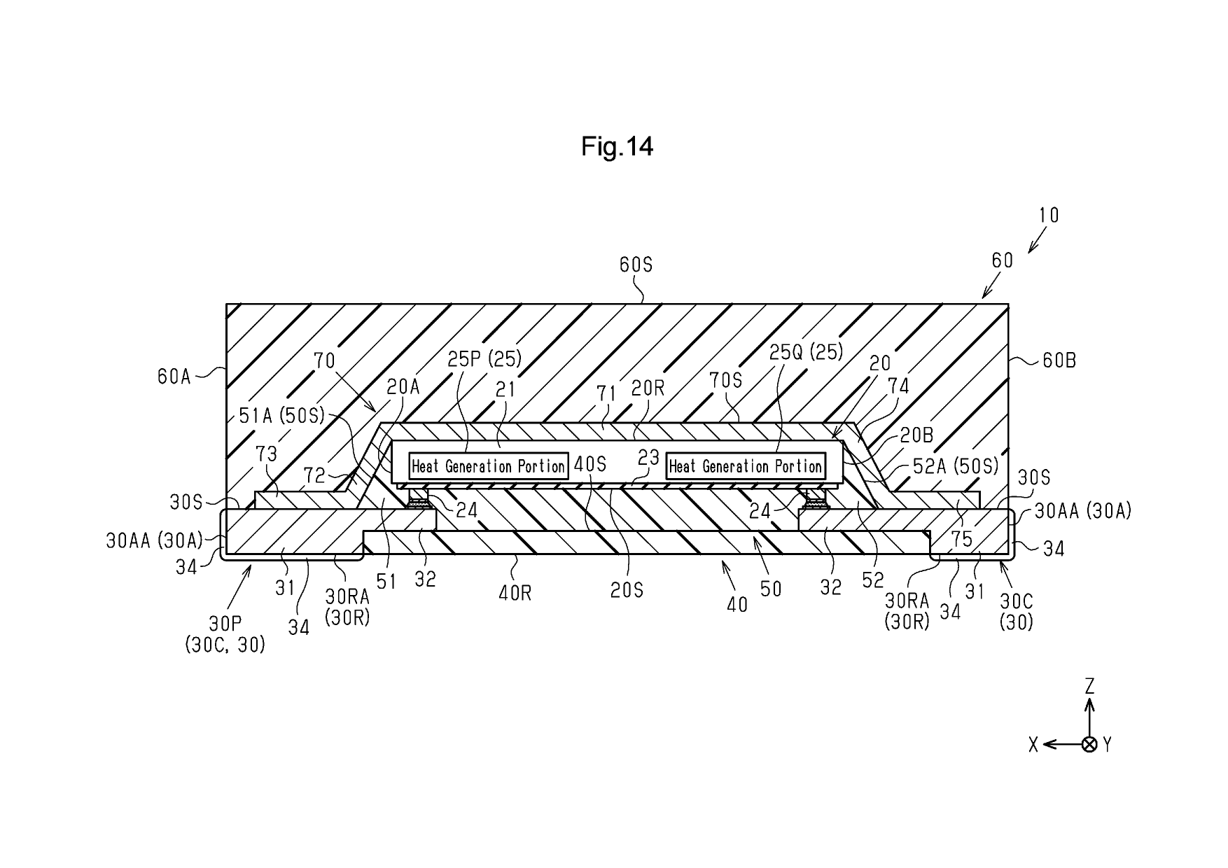

As shown in FIGS. 13 and 14, the heat dissipation member 70 is in contact with the terminal head surface 30S of each of the first heat dissipation terminal 30P and the second heat dissipation terminal 30Q. More specifically, the heat dissipation member 70 includes the second heat dissipation portion 72 that is contact with the sloped surface 51A of the first cover portion 51 of the first encapsulation resin 50, the third heat dissipation portion 73 that is in contact with a region of the terminal head surface 30S of the first heat dissipation terminal 30P that corresponds to the through-wiring portion 31, a fourth heat dissipation portion 74 that is in contact with a sloped surface 52A of the second cover portion 52 of the first encapsulation resin 50, and a fifth heat dissipation portion 75 that is in contact with a region of the terminal head surface 30S of the second heat dissipation terminal 30Q that corresponds to the through-wiring portion 31. The fourth heat dissipation portion 74 is connected to the first heat dissipation portion 71. The fifth heat dissipation portion 75 is connected to the fourth heat dissipation portion 74. In this manner, the first to fifth heat dissipation portions 71 to 75 are integrated with each other.

As shown in FIG. 13, the fourth heat dissipation portion 74 is formed on part of the second cover portion 52 in the Y-direction. The fourth heat dissipation portion 74 extends over the entirety of the second cover portion 52 in the X-direction. The fifth heat dissipation portion 75 extends over the entirety of a region of the terminal head surface 30S of the second heat dissipation terminal 30Q that corresponds to one of the two through-wiring portions 31.

With this structure, heat of the semiconductor chip 20 is transferred through two heat conduction paths, namely, a first heat conduction path to the first heat dissipation terminal 30P and a second heat conduction path to the second heat dissipation terminal 30Q. These heat conduction paths facilitate conduction of heat from the semiconductor chip 20 to a wiring board on which the semiconductor device 10 is mounted.

In an example, as shown in FIG. 13, the semiconductor chip 20 may include multiple heat generation portions 25, namely, a first heat generation portion 25P and a second heat generation portion 25Q. The first heat generation portion 25P and the second heat generation portion 25Q are spaced apart from each other in plan view. The first heat generation portion 25P is located relatively close to the first chip side surface 20A and the fourth chip side surface 20D in plan view. The second heat generation portion 25Q is located relatively close to the second chip side surface 20B and the third chip side surface 20C in plan view.

The first heat dissipation terminal 30P is located adjacent to the first heat generation portion 25P in the X-direction in plan view. The first heat dissipation terminal 30P is located adjacent to the first chip side surface 20A of the semiconductor chip 20 in the X-direction. The first heat generation portion 25P is located adjacent to the first cover portion 51 of the first encapsulation resin 50 in the X-direction. The second heat dissipation portion 72 of the heat dissipation member 70 is formed on the sloped surface 51A of the first cover portion 51, and thus the second heat dissipation portion 72 is located adjacent to the first heat generation portion 25P in the X-direction in plan view.

The second heat dissipation terminal 30Q is located adjacent to the second heat generation portion 25Q in the X-direction in plan view. The second heat dissipation terminal 30Q is located adjacent to the second chip side surface 20B of the semiconductor chip 20 in the X-direction. The second heat generation portion 25Q is located adjacent to the second cover portion 52 of the first encapsulation resin 50 in the X-direction. The fourth heat dissipation portion 74 of the heat dissipation member 70 is formed on the sloped surfaces 52A of the second cover portion 52, and thus the fourth heat dissipation portion 74 is located adjacent to the second heat generation portion 25Q in the X-direction in plan view.

The first heat dissipation portion 71 of the heat dissipation member 70 may be formed on part of the chip back surface 20R of the semiconductor chip 20 in plan view. In this case, the first heat dissipation portion 71 may be located at a position that overlaps the heat generation portion 25 of the semiconductor chip 20 in plan view.

The third heat dissipation portion 73 of the heat dissipation member 70 may be in contact with the entirety of a region of the terminal head surface 30S of the heat dissipation terminal 30P that corresponds to the through-wiring portions 31.

The third heat dissipation portion 73 of the heat dissipation member 70 may be in contact with the terminal head surface 30S of the heat dissipation terminal 30P that corresponds to each of the head surface joining portion 33 and the two through-wiring portions 31.

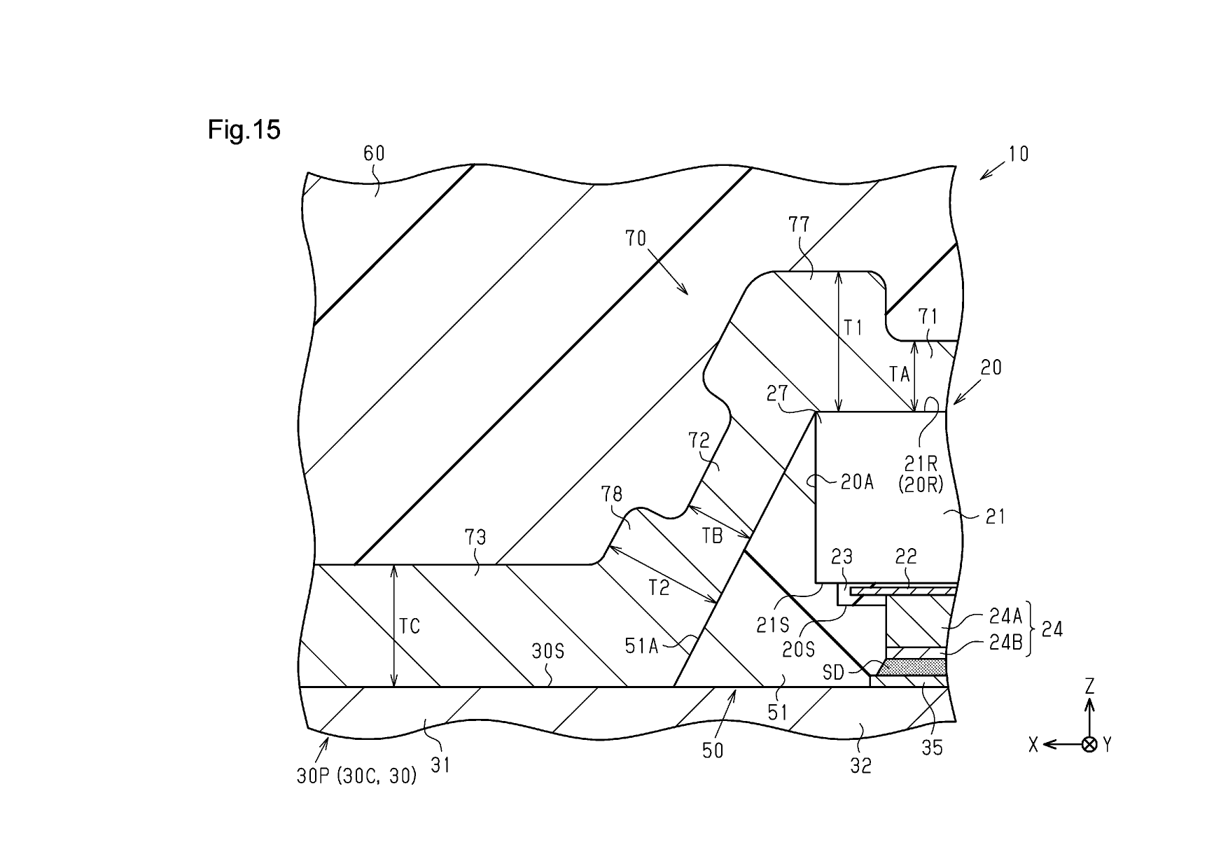

The heat dissipation member 70 may include a region that is relatively thick. In an example, as shown in FIG. 15, the heat dissipation member 70 may include a first stacked segment 77 formed at the boundary of the first heat dissipation portion 71 and the second heat dissipation portion 72, and a second stacked segment 78 formed at the boundary of the second heat dissipation portion 72 and the third heat dissipation portion 73. In an example, the third heat dissipation portion 73 may be thicker than the first heat dissipation portion 71.

The first stacked segment 77 extends over the boundary of the semiconductor chip 20 and the first cover portion 51 of the first encapsulation resin 50. The second stacked segment 78 extends over the boundary of the first cover portion 51 and a region of the terminal head surface 30S of the heat dissipation terminal 30P that corresponds to the through-wiring portion 31. A thickness T1 of the first stacked segment 77 is greater than a thickness TB of a part of the second heat dissipation portion 72 that is located between the first stacked segment 77 and the second stacked segment 78. The thickness T1 of the first stacked segment 77 is greater than, for example, a thickness TA of the first heat dissipation portion 71. A thickness T2 of the second stacked segment 78 is greater than the thickness TB of the part of the second heat dissipation portion 72 that is located between the first stacked segment 77 and the second stacked segment 78. In the example shown in FIG. 15, the thickness T1 of the first stacked segment 77 is greater than the thickness T2 of the second stacked segment 78. In the example shown in FIG. 15, the thickness T2 of the second stacked segment 78 is less than or equal to a thickness TC of the third heat dissipation portion 73. The first stacked segment 77 and the second stacked segment 78 are both formed by, for example, stacking dots 76 (refer to FIG. 5) of a conductive ink.

With this structure, the heat dissipation member 70 includes a relatively thick segment that is formed on the boundary between the first cover portion 51 and the semiconductor chip 20, where a step is likely to be formed. This avoids separation of the heat dissipation member 70 caused by such a step. Further, the heat dissipation member 70 includes a relatively thick segment that is formed on the boundary between the first cover portion 51 and the heat dissipation terminal 30P, where a step is likely to be formed. This avoids separation of the heat dissipation member 70 caused by such a step. As a result, heat is readily conducted from the first heat dissipation portion 71 through the second heat dissipation portion 72 to the third heat dissipation portion 73.

The relationship between the thickness T1 of the first stacked segment 77 and the thickness T2 of the second stacked segment 78 may be changed. In an example, the thickness T1 of the first stacked segment 77 may be less than or equal to the thickness T2 of the second stacked segment 78. Furthermore, the thickness T2 of the second stacked segment 78 may be greater than the thickness TC of the third heat dissipation portion 73.

The heat dissipation member 70 may be formed by a metal film, instead of being formed by ink-jet printing.

The first encapsulation resin 50 may be formed from a material having a thermal conductivity that is lower than or equal to that of air.

The first encapsulation resin 50 and the second encapsulation resin 60 may be formed from the same material.

The sloped surface 51A of the first cover portion 51 of the first encapsulation resin 50 does not have to have a curved concave shape, as shown in FIG. 6. In an example, the sloped surface 51A may be a flat surface that is sloped toward the substrate head surface 40S as the sloped surface 51A extends away from the first chip side surface 20A of the semiconductor chip 20.

The first encapsulation resin 50 may cover the entirety of the terminal head surface 30S of the substrate terminals 30, except for the terminal head surface 30S of the heat dissipation terminal 30P. In this case, the second heat dissipation portion 72 of the heat dissipation member 70 may extend over, for example, the entirety of the sloped surface 51A of the first cover portion 51. Furthermore, the second heat dissipation portion 72 may extend over, for example, the entirety of the sloped surface of at least one of the second to fourth cover portions 52 to 54. In an example, the second heat dissipation portion 72 may extend over the entirety of the sloped surface of the first to fourth cover portions 51 to 54. With this structure, the heat dissipation member 70 efficiently dissipates heat of the semiconductor chip 20.

The first encapsulation resin 50 does not have to cover the terminal head surface 30S of the heat dissipation terminal 30P that corresponds to the through-wiring portion 31.

The second encapsulation resin 60 may be omitted.

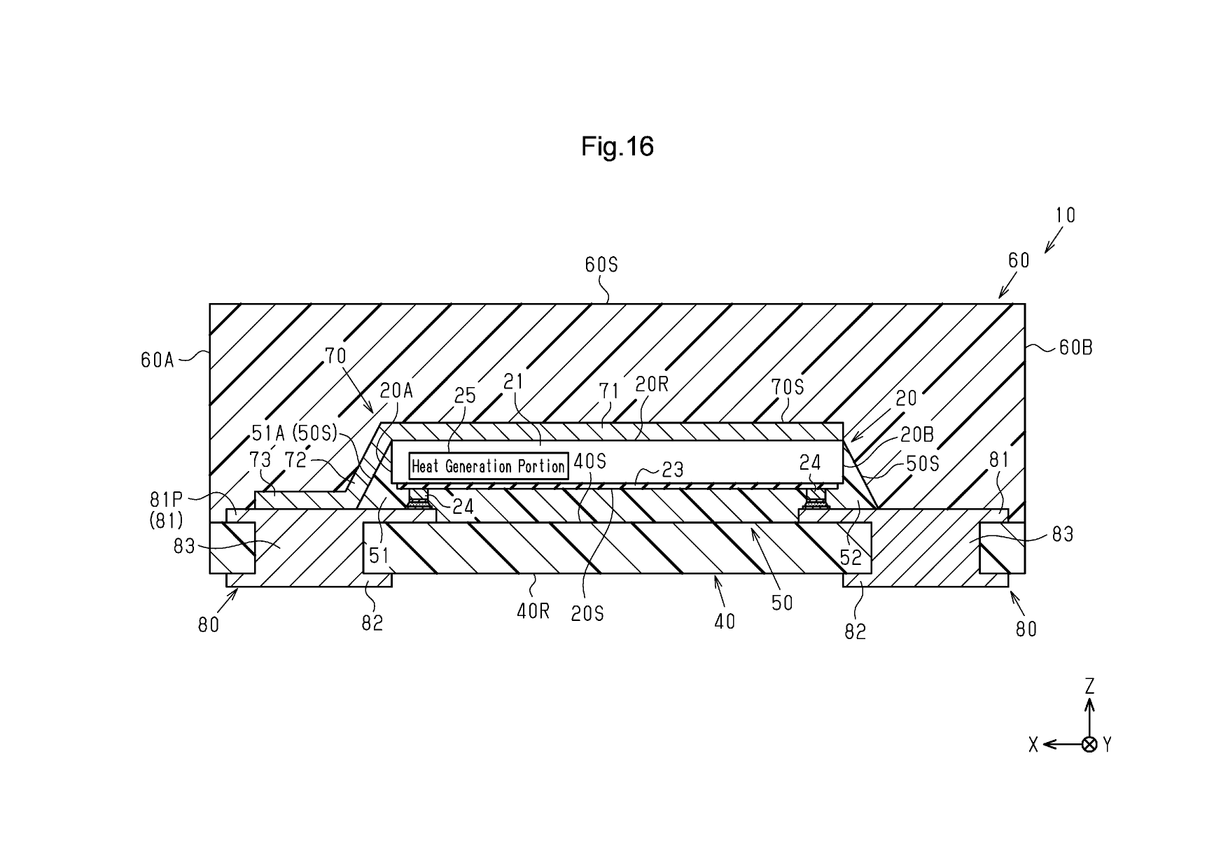

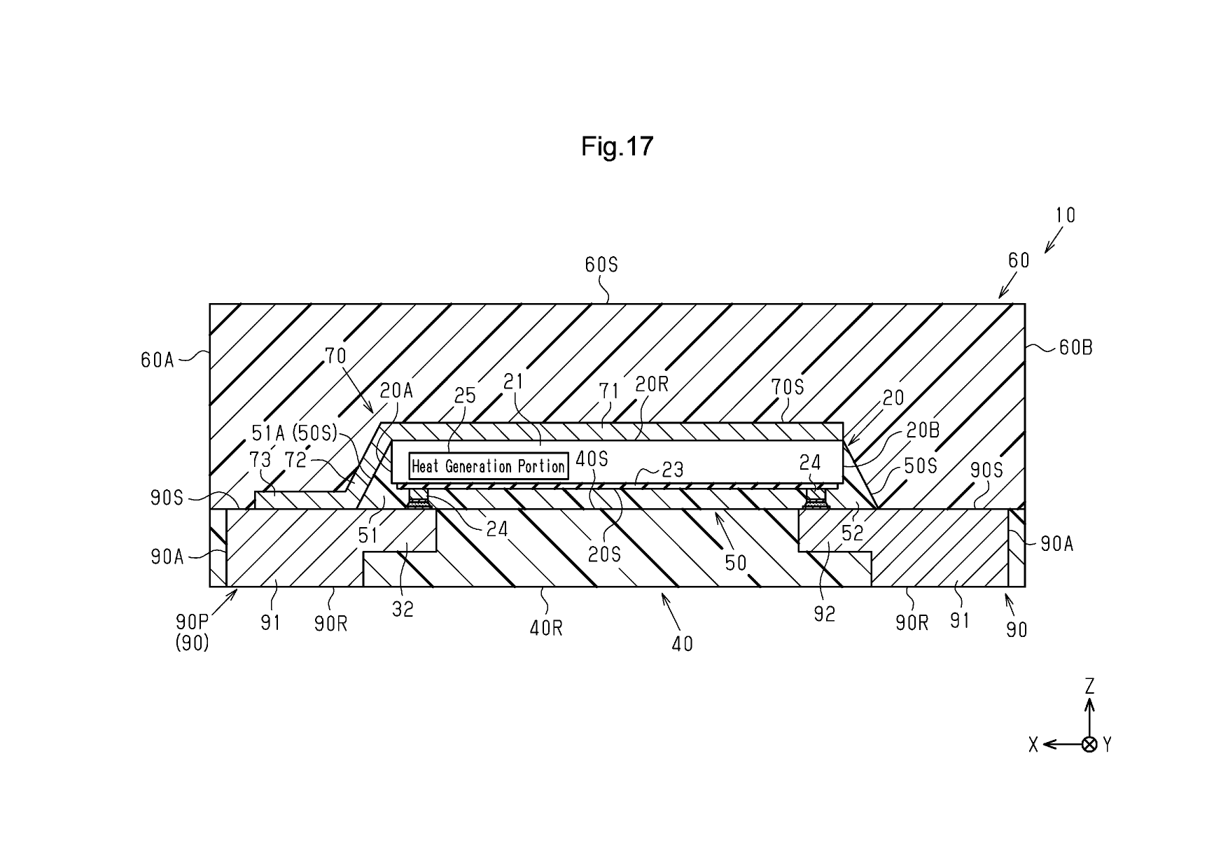

The structure of the semiconductor device 10 may be changed. In an example, the semiconductor device 10 may be changed in accordance with a first modified example shown in FIG. 16 or a second modified example shown in FIG. 17.

### First Modified Example

As shown in FIG. 16, the semiconductor device 10 includes electrode terminals 80 instead of the substrate terminals 30 (refer to FIG. 4). The electrode terminals 80 each include a head surface electrode 81, a back surface electrode 82, and a through-via 83. The head surface electrode 81 is formed on the substrate head surface 40S of the substrate 40. The head surface electrodes 81 are separated from each other on the substrate head surface 40S. The back surface electrode 82 is formed on the substrate back surface 40R of the substrate 40. The back surface electrodes 82 are separated from each other on the substrate back surface 40R. The through-via 83 extends through the substrate 40 in the Z-direction. The through-via 83 electrically connects a corresponding head surface electrode 81 and a corresponding back surface electrode 82. Accordingly, the head surface electrodes 81 are separately electrically connected to the back surface electrodes 82 by the through-vias 83. The head surface electrode 81, the back surface electrode 82, and the through-via 83 may be separate elements. Hence, the head surface electrode 81, the back surface electrode 82, and the through-via 83 may be formed from different materials. In an example, the head surface electrode 81 is formed from a material including at least one of Cu and Al. The back surface electrode 82 is formed from a material including at least one of Ni, Pd, and Au. The through-via 83 is formed from a material including at least one of Cu and Al.

In an example, the planar shapes and layout of the head surface electrodes 81 are the same as those of the substrate terminals 30 of the above-described embodiment. The planar shapes and layout of the head surface electrodes 81 may be changed.

The semiconductor chip 20 is mounted on the head surface electrodes 81. More specifically, the chip terminals 24 of the semiconductor chip 20 are separately electrically connected to the head surface electrodes 81. The chip terminals 24 and the head surface electrodes 81 are bonded to each other in the same manner as, for example, the chip terminals 24 and the substrate terminals 30 of the above-described embodiment.

The head surface electrodes 81 include a heat dissipation electrode 81P that has a portion located outward from the semiconductor chip 20 in plan view. In an example, the location of the heat dissipation electrode 81P in plan view is the same as that of the heat dissipation terminal 30P of the above-described embodiment. The location of the heat dissipation electrode 81P may be changed.

The heat dissipation member 70 is in contact with each of the chip back surface 20R of the semiconductor chip 20, the encapsulation head surface 50S of the first encapsulation resin 50 (sloped surface 51A of first cover portion 51), and the heat dissipation electrode 81P. The heat dissipation member 70 of the present example has the same shape as, for example, the heat dissipation member of the above-described embodiment.

A method for manufacturing the semiconductor device 10 of the first modified example mainly differs from that of the above-described embodiment in the preparing the substrate 40. More specifically, although not shown in the drawings, through holes are formed in the substrate base material 840 for the through-vias 83. The through holes are then filled with a metal material to form the through-vias 83. Subsequently, the head surface electrodes 81 are formed on the substrate head surface 841 of the substrate base material 840. Further, the back surface electrodes 82 are formed on the substrate back surface 842 of the substrate base material 840. In an example, the through-vias 83, the head surface electrodes 81, and the back surface electrodes 82 may be formed by plating.

In the method for manufacturing the semiconductor device 10 of the first modified example, the semiconductor chip 20 is mounted on the head surface electrodes 81. The mounting process is the same as that of the above-described embodiment.

The method for manufacturing the semiconductor device 10 of the first modified example includes forming the heat dissipation member 70 to be in contact with each of the chip back surface 20R, the encapsulation head surface 50S of the first encapsulation resin 50, and the heat dissipation electrode 81P. The heat dissipation member 70 is formed by, for example, ink-jet printing in the same manner as the above-described embodiment. The semiconductor device 10 of the first modified example has the same advantages as the above-described embodiment.

### Second Modified Example

As shown in FIG. 17, the semiconductor device 10 includes, instead of the substrate terminals 30, substrate terminals 90 formed by a lead frame. The substrate terminals 90 each include a terminal head surface 90S and a terminal back surface 90R that face away from each other in the Z-direction. The terminal head surface 90S faces the same direction as the substrate head surface 40S of the substrate 40. The terminal back surface 90R faces the same direction as the substrate back surface 40R. The terminal head surface 90S is exposed from the substrate head surface 40S. In an example, the terminal head surface 90S is flush with the substrate head surface 40S.

The substrate terminals 90 each include a through-wiring portion 91 that extends through the substrate 40, and a thin portion 92 that is thinner than the through-wiring portion 91. The terminal head surface 90S is flat and continuously extends over the through-wiring portion 91 and the thin portion 92.

A portion of the terminal back surface 90R that corresponds to the through-wiring portion 91 is exposed from the substrate back surface 40R. In an example, the portion of the terminal back surface 90R that corresponds to the through-wiring portion 91 is flush with the substrate back surface 40R. In the second modified example, a region of the terminal side surface 90A that corresponds to the through-wiring portion 91 of the substrate terminal 90 is not exposed from the substrate 40. The region of the terminal side surfaces 90A that corresponds to the through-wiring portion 91 of the substrate terminal 90 may be exposed from a corresponding one of the first to fourth substrate side surfaces 40A to 40D of the substrate 40.

The thin portion 92 is located inside the substrate 40 in the Z-direction. The thin portion 92 extends from the through-wiring portion 91 in a direction that intersects the Z-direction. The thin portion 92 includes a part located at a position that overlaps the semiconductor chip 20 in plan view. The chip terminal 24 of the semiconductor chip 20 is electrically connected to the thin portion 92.

The substrate terminals 90 include a heat dissipation terminal 90P that has a portion located outward from the semiconductor chip 20 in plan view. The heat dissipation member 70 of the present example has the same shape as, for example, the heat dissipation member of the above-described embodiment.

The heat dissipation member 70 is in contact with each of the chip back surface 20R of the semiconductor chip 20, the encapsulation head surface 50S of the first encapsulation resin 50 (sloped surface 51A of first cover portion 51), and the heat dissipation terminal 90P. The heat dissipation member 70 of the present example has the same shape as, for example, the heat dissipation member 70 of the above-described embodiment. The semiconductor device 10 of the second modified example has the same advantages as the above-described embodiment.

Various examples described in this specification may be combined as long as there is no technical contradiction.

In the present disclosure, the term “on” includes the meaning of “above” in addition to the meaning of “on” unless otherwise described in the context. Accordingly, for example, a phrase such as “first element disposed on second element” may mean that the first element is directly located on the second element in one embodiment and that the first element is located above the second element without contacting the second element in another embodiment. Therefore, the term “on” does not exclude a structure in which another element is formed between the first element and the second element.

The Z-direction as referred to in this disclosure does not have to be the vertical direction, and does not have to exactly coincide with the vertical direction. Accordingly, in the various structures of the present disclosure, “up” and “down” in the Z-direction as referred to in this specification are not limited to “up” and “down” in the vertical direction. For example, the vertical direction may be the X-direction or the Y-direction.

### Clauses

Technical concepts that can be understood from the present disclosure will now be described. Reference characters used in the described embodiment are added to corresponding elements in the clauses to aid understanding without any intention to impose limitations on these elements. The reference characters are given as examples to aid understanding, and are not intended to limit elements to the elements denoted by the reference characters.

### Clause 1

A semiconductor device (10), including:

a substrate (40) including a substrate head surface (40S) and a substrate back surface (40R) opposite to the substrate head surface (40S);

substrate terminals (30) extending through the substrate (40) in a thickness-wise direction (Z-direction) of the substrate (40), the substrate terminals (30) each including a terminal head surface (30S) exposed from the substrate head surface (40S), and a terminal back surface (30R) including a portion exposed from the substrate back surface (40R);

a semiconductor chip (20) including a chip head surface (20S) facing the terminal head surface (30S), a chip back surface (20R) opposite to the chip head surface (20S), a chip side surface (20A to 20D) connecting the chip head surface (20S) and the chip back surface (20R), and chip terminals (24) formed on the chip head surface (20S) and electrically connected to the terminal head surface (30S) of the substrate terminals (30); and

a first encapsulation resin (50) covering the chip head surface (20S) and the chip side surface (20A to 20D) of the semiconductor chip (20), in which

the substrate terminals (30) include a heat dissipation terminal (30P) having a portion located outward from the semiconductor chip (20) as viewed in the thickness-wise direction (Z-direction) of the semiconductor chip (20), and

the semiconductor device (10) further includes a heat dissipation member (70) being in contact with each of the chip back surface (20R), an encapsulation head surface (50S) of the first encapsulation resin (50), and the terminal head surface (30S) of the heat dissipation terminal (30P).

### Clause 2

The semiconductor device according to clause 1, in which the heat dissipation member (70) is formed from a conductive ink.

### Clause 3

The semiconductor device according to clauses 1 or 2, in which the heat dissipation member (70) extends over an entirety of the chip back surface (20R).

### Clause 4

The semiconductor device according to any one of clauses 1 to 3, in which the first encapsulation resin (50) fills a gap between the chip head surface (20S) of the semiconductor chip (20) and the substrate head surface (40S) of the substrate (40).

### Clause 5

The semiconductor device according to clause 4, in which, as viewed in the thickness-wise direction (Z-direction) of the substrate (40), the first encapsulation resin (50) partially covers the substrate terminals (30) and the heat dissipation terminal (30P) arranged around the semiconductor chip (20).

### Clause 6

The semiconductor device according to clause 5, in which

the semiconductor chip (20) includes

a heat generation portion (25), and

a first chip side surface (20A) facing a first direction (X-direction) orthogonal to the thickness-wise direction (Z-direction) of the semiconductor chip (20), the chip side surface including the first chip side surface (20A),

the heat generation portion (25) is located relatively close to the first chip side surface (20A) with respect to a center of the semiconductor chip (20) in the first direction (X-direction),

as viewed in the thickness-wise direction (Z-direction) of the semiconductor chip (20), the heat dissipation terminal (30P) is located adjacent to the first chip side surface (20A) in the first direction (X-direction),

the first encapsulation resin (50) includes a first cover portion (51) covering the first chip side surface (20A), and

the heat dissipation member (70) is in contact with the first cover portion (51).

### Clause 7

The semiconductor device according to clause 6, in which the first cover portion (51) covers an entirety of the first chip side surface (20A) in the thickness-wise direction (Z-direction) of the semiconductor chip (20).

### Clause 8

The semiconductor device according to clause 7, in which

the first cover portion (51) includes, as the encapsulation head surface (50S), a sloped surface (51A) sloped toward the terminal head surface (30S) of the heat dissipation terminal (30P) as the sloped surface (51A) extends away from the first chip side surface (20A), and

the sloped surface (51A) is connected to a corner (27) formed by the chip back surface (20R) and the first chip side surface (20A).

### Clause 9

The semiconductor device according to clause 8, in which

the sloped surface (51A) of the first cover portion (51) has a curved concave shape, and

the heat dissipation member (70) includes a portion (72) being in contact with the sloped surface (51A), the portion following the curved concave shape of the sloped surface (51A).

### Clause 10

The semiconductor device according to any one of clauses 6 to 9, in which the first cover portion (51) covers a portion of the terminal head surface (30S) of the heat dissipation terminal (30P), the portion being located relatively close to the first chip side surface (20A).

### Clause 11

The semiconductor device according to any one of clauses 1 to 10, in which

the substrate terminals (30) each include a through-wiring portion (31) extending through the substrate (40) in the thickness-wise direction (Z-direction) of the substrate (40), and

the heat dissipation member (70) is in contact with the terminal head surface (30S) corresponding to the through-wiring portion (31) of the heat dissipation terminal (30P).

### Clause 12

The semiconductor device according to clause 11, in which the substrate terminals (30) each include a head surface wiring portion (32) extending from the through-wiring portion (31) along the substrate head surface (40S).

### Clause 13

The semiconductor device according to clause 12, in which

the head surface wiring portion (32) includes a part located at a position overlapping the semiconductor chip (20) as viewed in the thickness-wise direction (Z-direction) of the substrate (40), and

the chip terminals (24) are each electrically connected to the head surface wiring portion (32).

### Clause 14

The semiconductor device according to any one of clauses 1 to 10, in which

the substrate terminals (90) each include

a through-wiring portion (91) extending through the substrate (40), and

a thin portion (92) thinner than the through-wiring portion (91) and located inside the substrate (40) in the thickness-wise direction (Z-direction) of the substrate (40),

the thin portion (92) extends from the through-wiring portion (91) in a direction intersecting the thickness-wise direction (Z-direction) of the substrate (40), and

the heat dissipation member (70) is in contact with the terminal head surface (90S) corresponding to the through-wiring portion (91) of the heat dissipation terminal (90P).

### Clause 15

The semiconductor device according to clause 14, in which

the thin portion (92) includes a part located at a position overlapping the semiconductor chip (20) as viewed in the thickness-wise direction (Z-direction) of the substrate (40), and

the chip terminals (24) are each electrically connected to the thin portion (92).

### Clause 16

The semiconductor device according to any one of clauses 1 to 15, further including a second encapsulation resin (60), the second encapsulation resin (60) covering the first encapsulation resin (50), the heat dissipation member (70), and the chip back surface (20R).

### Clause 17

The semiconductor device according to clause 16, in which the first encapsulation resin (50) and the second encapsulation resin (60) are formed from different materials.

### Clause 18

The semiconductor device according to clause 17, in which the first encapsulation resin (50) has a higher thermal conductivity than the second encapsulation resin (60).

### Clause 19

The semiconductor device according to clause 16, in which the first encapsulation resin (50) has a higher thermal conductivity than air.

### Clause 20

The semiconductor device according to any one of clauses 1 to 19, in which the heat dissipation member (70) has a thickness in a range of 5 μm to 30 μm, inclusive.

### Clause 21

The semiconductor device according to any one of clauses 6 to 10, in which

the heat dissipation member (70) includes

a first heat dissipation portion (71) being in contact with the chip back surface (20R),

a second heat dissipation portion (72) being in contact with the first cover portion (51), and

a third heat dissipation portion (73) being in contact with the terminal head surface (30S) of the heat dissipation terminal (30P), and

the first heat dissipation portion (71), the second heat dissipation portion (72), and the third heat dissipation portion (73) are integrated with each other.

### Clause 22

The semiconductor device according to any one of clauses 1 to 21, in which

the heat dissipation terminal (30P) includes a terminal side surface (30A) connecting the terminal head surface (30S) and the terminal back surface (30R), and

at least part of the terminal side surface (30A/30AA) of the heat dissipation terminal (30P) is exposed from the substrate (40).

### Clause 23

The semiconductor device according to any one of clauses 1 to 22, in which the heat dissipation member (70) is formed from a material including at least one of Au, Cu, and Ag.

### Clause 24

The semiconductor device according to any one of clauses 1 to 23, in which the heat dissipation terminal (30P) is electrically floating.

### Clause 25

The semiconductor device according to any one of clauses 1 to 23, in which

the heat dissipation terminal (30P) of the substrate terminals (30) is one of heat dissipation terminals (30P), and

the heat dissipation member (70) is in contact with the terminal head surface (30S) of each of the heat dissipation terminals (30P).

### Clause 26

The semiconductor device according to clause 24, in which at least one of the heat dissipation terminals (30P) is electrically floating.

### Clause 27

The semiconductor device according to any one of clauses 1 to 26, in which

the heat dissipation member (70) includes a heat dissipation head surface (70S), and

the heat dissipation head surface (70S) has irregularities.

### Clause 28

The semiconductor device according to clause 1, in which the heat dissipation member (70) is formed by a metal film.

### Clause 29

The semiconductor device according to clause 16, in which the first encapsulation resin (50) and the second encapsulation resin (60) are formed from a same material.

### Clause 30

The semiconductor device according to clause 5, in which

the semiconductor chip (20) includes

a first heat generation portion (25P) and a second heat generation portion (25Q), and

a first chip side surface (20A) and a second chip side surface (20B) facing away from each other in a first direction (X-direction) orthogonal to the thickness-wise direction (Z-direction) of the semiconductor chip (20), the chip side surface including the first chip side surface (20A) and the second chip side surface (20B),

the first heat generation portion (25P) is located relatively close to the first chip side surface (20A) with respect to a center of the semiconductor chip (20) in the first direction (X-direction),

the second heat generation portion (25Q) is located relatively close to the second chip side surface (20B) with respect to the center of the semiconductor chip (20) in the first direction (X-direction),

the substrate terminals (30) include, as the heat dissipation terminal, a first heat dissipation terminal (30P) and a second heat dissipation terminal (30Q),

as viewed in the thickness-wise direction (Z-direction) of the semiconductor chip (20), the first heat dissipation terminal (30P) is located adjacent to the first chip side surface (20A) in the first direction (X-direction),

as viewed in the thickness-wise direction (Z-direction) of the semiconductor chip (20), the second heat dissipation terminal (30Q) is located adjacent to the second chip side surface (20B) in the first direction (X-direction),

the first encapsulation resin (50) includes

a first cover portion (51) covering the first chip side surface (20A), and

a second cover portion (52) covering the second chip side surface (20B), and

the heat dissipation member (70) is in contact with both the first cover portion (51) and the second cover portion (52).

### Clause 31

A semiconductor device (10), including:

a substrate (40) including a substrate head surface (40S) and a substrate back surface (40R) facing away from the substrate head surface (40S);

head surface electrodes (81) formed on the substrate head surface (40S);

a semiconductor chip (20) including a chip head surface (20S) facing the head surface electrodes (81), a chip back surface (20R) opposite to the chip head surface (20S), a chip side surface (20A to 20D) connecting the chip head surface (20S) and the chip back surface (20R), and chip terminals (24) formed on the chip head surface (20S) and electrically connected to the head surface electrodes (81); and

a first encapsulation resin (50) covering the chip head surface (20S) and the chip side surface (20A to 20D) of the semiconductor chip (20), in which

the head surface electrodes (81) include a heat dissipation electrode (81P) having a portion located outward from the semiconductor chip (20) as viewed in a thickness-wise direction (Z-direction) of the semiconductor chip (20), and

the semiconductor device (10) further includes a heat dissipation member (70) being in contact with each of the chip back surface (20R), an encapsulation head surface (50S) of the first encapsulation resin (50), and the heat dissipation electrode (81P).

### Clause 32

The semiconductor device according to clause 31, further including

back surface electrodes (82) formed on the substrate back surface (40R); and

through-vias (83) extending through the substrate (40) in the thickness-wise direction (Z-direction) of the substrate (40), the through-vias (83) separately electrically connecting the head surface electrodes (81) and the back surface electrodes (82).

### Clause 33

A method for manufacturing a semiconductor device (10), the method including:

preparing a substrate (840/40), the substrate (840/40) including a substrate head surface (40S), a substrate back surface (40R) opposite to the substrate head surface (40S), and substrate terminals (30), the substrate terminals (30) each including a terminal head surface (30S) exposed from the substrate head surface (40S), and a terminal back surface (30R) including a portion exposed from the substrate back surface (40R);

electrically connecting chip terminals (24) of a semiconductor chip (20) to the substrate terminals (30), the semiconductor chip (20) including a chip head surface (20S) facing the terminal head surface (30S), a chip back surface (20R) opposite to the chip head surface (20S), a chip side surface (20A to 20D) connecting the chip head surface (20S) and the chip back surface (20R), and the chip terminals (24) formed on the chip head surface (20S); and

forming a first encapsulation resin (50) to cover the chip head surface (20S) and the chip side surface (20A to 20D) of the semiconductor chip (20), in which

the substrate terminals (30) include a heat dissipation terminal (30P) having a portion located outward from the semiconductor chip (20) as viewed in a thickness-wise direction (Z-direction) of the semiconductor chip (20), and

the method further includes forming a heat dissipation member (70) to be in contact with each of the chip back surface (20R), an encapsulation head surface (50S) of the first encapsulation resin (50), and the terminal head surface (30S) of the heat dissipation terminal (30P).

### Clause 34

The method according to clause 33, in which the heat dissipation member (70) is formed by ink-jet printing.

### Clause 35

The method according to clause 33 or 34, further including, after the forming the heat dissipation member (70), forming a second encapsulation resin (60) to cover the first encapsulation resin (50) and the heat dissipation member (70).

### Clause 36

A method for manufacturing a semiconductor device (10), the method including:

preparing a substrate (840/40), the substrate (840/40) including a substrate head surface (40S), a substrate back surface (40R) facing away from the substrate head surface (40S), and head surface electrodes (81) formed on the substrate head surface (40S);

electrically connecting chip terminals (24) of a semiconductor chip (20) to the head surface electrodes (81), the semiconductor chip (20) including a chip head surface (20S) facing the head surface electrodes (81), a chip back surface (20R) opposite to the chip head surface (20S), a chip side surface (20A to 20D) connecting the chip head surface (20S) and the chip back surface (20R), and the chip terminals (24) formed on the chip head surface (20S); and

forming a first encapsulation resin (50) to cover the chip head surface (20S) and the chip side surface (20A to 20D) of the semiconductor chip (20), in which

the head surface electrodes (81) include a heat dissipation electrode (81P) having a portion located outward from the semiconductor chip (20) as viewed in a thickness-wise direction (Z-direction) of the semiconductor chip (20), and

the method further includes forming a heat dissipation member (70) to be in contact with each of the chip back surface (20R), an encapsulation head surface (50S) of the first encapsulation resin (50), and the heat dissipation electrode (81P).

The above descriptions are merely exemplary. One skilled in the art would recognize the potential for a wide variety of combinations and substitutions of the elements and methods (manufacturing processes) in addition to those illustrated to describe the techniques of this disclosure. Any substitutions, modifications, and variations within the scope of the claims are intended to be encompassed in the present disclosure.

Various changes in form and details may be made to the examples above without departing from the spirit and scope of the claims and their equivalents. The examples are for the sake of description only, and not for purposes of limitation. Descriptions of features in each example are to be considered as being applicable to similar features or aspects in other examples. Suitable results may be achieved if sequences are performed in a different order, and/or if components in a described system, architecture, device, or circuit are combined differently, and/or replaced or supplemented by other components or their equivalents. The scope of the disclosure is not defined by the detailed description, but by the claims and their equivalents. All variations within the scope of the claims and their equivalents are included in the disclosure.

What is claimed is:

1. A semiconductor device, comprising:
a substrate including a substrate head surface and a substrate back surface opposite to the substrate head surface;
substrate terminals extending through the substrate in a thickness-wise direction of the substrate, the substrate terminals each including a terminal head surface exposed from the substrate head surface, and a terminal back surface including a portion exposed from the substrate back surface;
a semiconductor chip including a chip head surface facing the terminal head surface, a chip back surface opposite to the chip head surface, a chip side surface connecting the chip head surface and the chip back surface, and chip terminals formed on the chip head surface and electrically connected to the terminal head surface of the substrate terminals; and
a first encapsulation resin covering the chip head surface and the chip side surface of the semiconductor chip, wherein
the substrate terminals include a heat dissipation terminal having a portion located outward from the semiconductor chip as viewed in the thickness-wise direction of the semiconductor chip, and
the semiconductor device further comprises a heat dissipation member being in contact with each of the chip back surface, an encapsulation head surface of the first encapsulation resin, and the terminal head surface of the heat dissipation terminal.

2. The semiconductor device according to claim 1, wherein the heat dissipation member is formed from a conductive ink.

3. The semiconductor device according to claim 1, wherein the heat dissipation member extends over an entirety of the chip back surface.

4. The semiconductor device according to claim 1, wherein the first encapsulation resin fills a gap between the chip head surface of the semiconductor chip and the substrate head surface of the substrate.

5. The semiconductor device according to claim 4, wherein, as viewed in the thickness-wise direction of the substrate, the first encapsulation resin partially covers the substrate terminals and the heat dissipation terminal arranged around the semiconductor chip.

6. The semiconductor device according to claim 5, wherein
the semiconductor chip includes
a heat generation portion, and
a first chip side surface facing a first direction orthogonal to the thickness-wise direction of the semiconductor chip, the chip side surface including the first chip side surface,
the heat generation portion is located relatively close to the first chip side surface with respect to a center of the semiconductor chip in the first direction,
as viewed in the thickness-wise direction of the semiconductor chip, the heat dissipation terminal is located adjacent to the first chip side surface in the first direction,
the first encapsulation resin includes a first cover portion covering the first chip side surface, and
the heat dissipation member is in contact with the first cover portion.

7. The semiconductor device according to claim 6, wherein the first cover portion covers an entirety of the first chip side surface in the thickness-wise direction of the semiconductor chip.

8. The semiconductor device according to claim 7, wherein
the first cover portion includes, as the encapsulation head surface, a sloped surface sloped toward the terminal head surface of the heat dissipation terminal as the sloped surface extends away from the first chip side surface, and
the sloped surface is connected to a corner formed by the chip back surface and the first chip side surface.

9. The semiconductor device according to claim 8, wherein
the sloped surface of the first cover portion has a curved concave shape, and
the heat dissipation member includes a portion being in contact with the sloped surface, the portion following the curved concave shape of the sloped surface.

10. The semiconductor device according to claim 6, wherein the first cover portion covers a portion of the terminal head surface of the heat dissipation terminal, the portion being located relatively close to the first chip side surface.

11. The semiconductor device according to claim 1, wherein
the substrate terminals each include a through-wiring portion extending through the substrate in the thickness-wise direction of the substrate, and
the heat dissipation member is in contact with the terminal head surface corresponding to the through-wiring portion of the heat dissipation terminal.

12. The semiconductor device according to claim 11, wherein the substrate terminals each include a head surface wiring portion extending from the through-wiring portion along the substrate head surface.

13. The semiconductor device according to claim 12, wherein
the head surface wiring portion includes a part located at a position overlapping the semiconductor chip as viewed in the thickness-wise direction of the substrate, and
the chip terminals are each electrically connected to the head surface wiring portion.

14. The semiconductor device according to claim 1, wherein
the substrate terminals each include
a through-wiring portion extending through the substrate, and
a thin portion thinner than the through-wiring portion and located inside the substrate in the thickness-wise direction of the substrate,
the thin portion extends from the through-wiring portion in a direction intersecting the thickness-wise direction of the substrate, and
the heat dissipation member is in contact with the terminal head surface corresponding to the through-wiring portion of the heat dissipation terminal.

15. The semiconductor device according to claim 14, wherein
the thin portion includes a part located at a position overlapping the semiconductor chip as viewed in the thickness-wise direction of the substrate, and
the chip terminals are each electrically connected to the thin portion.

16. The semiconductor device according to claim 1, further comprising a second encapsulation resin, the second encapsulation resin covering the first encapsulation resin, the heat dissipation member, and the chip back surface.

17. The semiconductor device according to claim 16, wherein the first encapsulation resin and the second encapsulation resin are formed from different materials.

18. The semiconductor device according to claim 17, wherein the first encapsulation resin has a higher thermal conductivity than the second encapsulation resin.

19. The semiconductor device according to claim 16, wherein the first encapsulation resin has a higher thermal conductivity than air.

20. The semiconductor device according to claim 1, wherein the heat dissipation member has a thickness in a range of 5 μm to 30 μm, inclusive.
